(19) United States
(12) Patent Application Publication
(10) Pub. No.: US 2026/0190287 A1
(43) Pub. Date: Jul. 2, 2026

(54) SYSTEMS FOR COOLING OF COMPUTING DEVICES USING LIQUID IMMERSION

(71) Applicant: FIRMUS METAL TECHNOLOGIES SINGAPORE PTE LTD, Singapore (SG)

(72) Inventors: Hamish Kerr, Cremorne (AU); Andrew BULS, Cremorne (AU); Oliver CURTIS, Cremorne (AU); Jonathan LEVEE, Cremorne (AU)

(21) Appl. No.: 19/128,634

(22) PCT Filed: Nov. 10, 2023
(86) PCT No.: PCT/AU2023/051135

§ 371 Date: May 9, 2025

(30) Foreign Application Priority Data
Nov. 10, 2022 (AU) 2022903367
Nov. 10, 2022 (AU) 2022903371
Nov. 10, 2022 (AU) 2022903375

(51) Int. Cl. H05K 7/20

(52) U.S. Cl. CPC H05K 7/20272; H05K 7/20236; H05K 7/20263; H05K 7/20772; H05K 7/20836

(57) ABSTRACT

Embodiments generally relate to systems for cooling computing devices using liquid immersion. An example system includes: a plurality of open cooling tanks, each cooling tank defining an interior volume to receive computing devices and to receive a non-conductive liquid coolant; coolant supply conduits, including a supply header conduit and a plurality of supply branch conduits, each of the supply branch conduits fluidly coupling the supply header conduit to a respective cooling tank, wherein a diameter of the supply header conduit is larger than a diameter of the supply branch conduits; coolant return conduits, including a return header conduit and a plurality of return branch conduits, each of the return branch conduits fluidly coupling the return header conduit to a respective cooling tank, wherein a diameter of the return header conduit is larger than a diameter of the return branch conduits; at least one heat exchanger; and a pump system fluidly coupled to the at least one heat exchanger, the supply header conduit and the return header conduit to cause liquid coolant to flow in a closed circuit through the at least one heat exchanger and through each of the tanks simultaneously via the supply branch conduits and the return branch conduits.

### TECHNICAL FIELD

Described embodiments relate to systems for cooling computing devices. In some embodiments, the systems comprise components for facilitating flow of cooling fluid for cooling computing devices.

### BACKGROUND

A data centre usually hosts hundreds, thousands, or tens of thousands of computing devices or servers to perform computing tasks. These computing devices generate a huge amount of heat during operation. The heat generated from the computing devices must be dissipated for the computing devices to operate properly. Otherwise, the computing devices may be damaged due to the accumulated heat in the data centre. Therefore, a cooling system is required to be installed in the data centre to dissipate the heat.

Both the computing devices and the cooling system in the data centre consume electricity. Power Usage Effectiveness (PUE) is used to measure the effectiveness of power usage, which is defined as a ratio of total power consumed by a data centre to the power delivered to the computing devices or severs performing the computing tasks. For example, a data centre may consume a total power of 10,000 KW, which is used to power the servers and other equipment. Primarily, the other equipment includes the cooling system to cool the servers. In this example, 8,000 KW out of the total power may be used to power the servers. Therefore, the PUE of the data centre would be 10,000 KW/8,000 KW=1.25. Usually, a lower PUE means less wastage of electricity, lower operating costs, and more competitive advantages.

It is desired to address or ameliorate one or more disadvantages associated with such prior methods and systems, or at least to provide a useful alternative thereto.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each of the appended claims.

### SUMMARY

Some of the present disclosures are directed to a cooling system for facilitating cooling of computing devices, the cooling system comprising: optionally one or more mounting racks; a plurality of cooling tanks arranged into one or more rows, configured to accommodate a liquid coolant and sized to immerse a plurality of computing devices in the liquid coolant when the liquid coolant is located in the tanks in order for the liquid coolant to absorb heat generated from the computing devices; wherein the plurality of cooling tanks are affixed to the one or more mounting racks (if present), each cooling tank being arranged proximal to at least one other cooling tank; a heat dissipater configured to receive the liquid coolant carrying the heat absorbed from the computing devices and to dissipate heat from the liquid coolant; a coolant pump configured to facilitate circulation of the liquid coolant through the cooling system; and a pair of coolant conduits, the pair of coolant conduits comprising an inlet conduit and an outlet conduit, and each row of coolant tanks comprising at least one pair of coolant conduits extending substantially along the length of the row, and the pair of coolant conduits are in fluidic communication with the heat dissipater, and the coolant pump; one or more branch conduits in fluidic connection with the plurality of cooling tanks and the pair of coolant conduits and configured to convey the liquid coolant into and out of the plurality of cooling tanks; wherein the branch conduits comprise at least one inlet branch conduit and at least one outlet branch conduit; wherein the one or more pairs of coolant conduits and the one or more branch conduits are configured to convey liquid coolant throughout the cooling system during operation to absorb heat from the plurality of computing devices and transport the coolant to the heat exchanger to dissipate the absorbed heat; and wherein the pair of coolant conduits and the one or more branch conduits are further configured to facilitate at least one of a transitional flow regime or a laminar flow regime of the liquid coolant through at least a portion of the cooling system.

In some embodiments, the coolant conduits are tubes. In some embodiments, the coolant conduits are pipes. In some embodiments, the coolant conduits are a combination of pipes and tubes.

In some embodiments, the branch conduits are tubes. In some embodiments, the branch conduits are pipes. In some embodiments, the branch conduits are a combination of tubes and pipes.

In some embodiments, the coolant conduits have an internal diameter of between about 100 mm and about 150 mm. In some embodiments, the branch conduits have an internal diameter of about 50 mm.

In some embodiments, the cooling system is configured to maintain: a differential pressure of less than 1 kPa and a maximum velocity pressure of less than 1 KPa in the inlet conduit; a differential pressure of less than 1 kPa and a maximum velocity pressure of less than 0.5 KPa in the outlet conduit; a differential pressure of greater than 15 kPa in the at least one inlet branch conduit; a differential pressure of greater than 2.4 kPa in the at least one outlet branch conduit.

In some embodiments, the cooling system is configured to maintain: a differential pressure of between 0.6 kPa and 1 kPa and a maximum velocity pressure of between 0.43 kPa and 1 KPa in the inlet conduit; a differential pressure of between 0.2 kPa and 1 kPa and a maximum velocity pressure of between 0.42 kPa and 0.5 KPa in the outlet conduit; a differential pressure of greater than 15 kPa in the at least one inlet branch conduit; a differential pressure of greater than 2.4 kPa in the at least one outlet branch conduit.

In some embodiments, the cooling system is configured to maintain: a differential pressure of between 0.25 kPa and 1 kPa and a maximum velocity pressure of between 0.53 kPa and 1 KPa in the inlet conduit; a differential pressure of between 0.18 kPa and 1 kPa and a maximum velocity pressure of between 0.20 kPa and 0.5 KPa in the outlet conduit; a differential pressure of greater than 15 kPa in the at least one inlet branch conduit; a differential pressure of greater than 2.4 kPa in the at least one outlet branch conduit.

In some embodiments, the cooling system is configured to maintain a flowrate of between 9 L/s and 16 L/s within the inlet conduit and the outlet conduit and flowrate of between 2.6 L/s and 3 L/s in the one or more branch conduits.

In some embodiments, the cooling system may comprise one or more additional rows of coolant tanks, each comprising a pair of coolant conduits may be added to the system to expand its capacity for cooling computing devices.

In some embodiments, the cooling system comprises a first set of coolant conduits and a second set of coolant conduits, and a wherein the one or more branch conduits are a first set of branch conduits and the cooling system further comprises a second set of branch conduits; wherein the second set of coolant conduits and the second set of branch conduits are a parallel system.

In some embodiments, the parallel system further comprises a coolant pump and/or a heat dissipater. In some embodiments, the average flow regime of the cooling system has a Reynolds number of between 2,300 and 4,000.

Some of the present disclosures are directed to a cooling system for facilitating cooling of computing devices according to any of the previous disclosures, wherein the cooling system comprises: one or more flange connections, at least one of the flange connections comprising: a first flange plate and a second flange plate configured to releasably connect to one another; a conduit body; a conduit end, the conduit end being non-releasably affixed to the conduit body, the conduit end comprising: a sealing portion configured to be received between the first and second flange plates and engage with a gasket, as to create a fluidic connection; and an elongate connecting portion, the elongate connecting portion extending substantially perpendicular to the sealing portion and configured to be received through the first flange plate; and wherein, the conduit end is formed from a single piece of conduit, and has a substantially uniform wall thickness.

In some embodiments, the conduit end is formed by a metal spinning process. In some embodiments, the conduit end is connected to the conduit body by a welding process. In some embodiments, the welding process uses an orbital welder.

In some embodiments, the elongate connection portion and the sealing portion are connected by a bend in the conduit. In some embodiments, In some embodiments, the cooling system further comprises a baffle plate between the first flange plate and the second flange plate, wherein the baffle plate is configured to disturb the flow of the coolant through the cooling system.

Some of the present disclosures are directed to a cooling system for facilitating cooling of computing devices according to any of the previous disclosures, wherein the cooling system comprises: one or more balance valves, the one or more balance valves being in fluidic communication with one or more branch conduits, each balance valve comprising: an inlet conduit and an outlet conduit, wherein the inlet and outlet conduits are adapted to interface with one or more branch conduits; one or more synthetic polymer O-rings; an actuating handle; and a flow control member, the flow control member being rotatable by the actuating handle; wherein when flow control member is rotated by the actuating handle, the flow control member is configured to restrict the flow of coolant through the balance valve by a percentage that is related to the percentage rotation of the actuating handle.

In some embodiments, the inlet and outlet conduits comprise a pipe to tube adaptor. In some embodiments, the flow control member is a W-port. In some embodiments, the cooling system of any one of the previous disclosures also comprises a volume of liquid coolant. In some embodiments, the cooling system of any one of the previous disclosures also comprises a plurality of computing devices disposed within the plurality of cooling tanks.

Some of the present disclosures are directed to a cooling system for facilitating cooling of computing devices, according to any one of the previous disclosures wherein: a first tank and a second tank each comprise: an inlet conduit and a balance conduit, the inlet conduit and balance conduit configured to receive an isolating member; a balance line in fluidic connection with a first balance conduit of the first tank and a second balance conduit of the second tank; wherein the balance line is configured to balance the volume of liquid coolant within the first tank and the second tank during operation, such that the first tank and the second tank comprise substantially the same volume of liquid coolant during normal operation of the cooling system; and wherein when an isolating member is received by the inlet conduit and the balance conduit of the first tank, and when an isolating member is received by the inlet conduit and the outlet conduit of the second tank, at least the first tank is caused to be fluidically disconnected from the cooling system.

In some embodiments, the isolating member comprises a threaded portion, and wherein the balance conduit and the outlet conduit of the first tank and the balance conduit and the outlet conduit of the second tank also comprise a threaded portion, configured to receive the isolating member. In some embodiments, the isolating member has a hollow cross section.

Some embodiments relate to a cooling system for facilitating cooling of computing devices, the cooling system comprising:
a plurality of cooling tanks arranged into one or more row(s), each tank configured to accommodate a liquid coolant and sized to immerse a plurality of computing devices in the liquid coolant when the liquid coolant is located in the tanks in order for the liquid coolant to absorb heat generated from the computing devices;
wherein each of the plurality of cooling tanks are arranged proximal to at least one other cooling tank;
a heat dissipater configured to receive the liquid coolant carrying the heat absorbed from the computing devices to dissipate the heat from the liquid coolant;
a pair of coolant conduits, the pair of coolant conduits comprising an inlet conduit and an outlet conduit, and each row of coolant tanks comprising at least one pair of coolant conduits extending substantially along the length of the row, and the pair of coolant conduits being in fluidic communication with the heat dissipater;
one or more branch conduits in fluidic connection with the plurality of cooling tanks and the pair of coolant conduits, the branch conduits being configured to convey the liquid coolant between the coolant tanks and the coolant conduits;
   wherein the branch conduits comprise at least one inlet branch conduit and at least one outlet branch conduit;
the one or more pairs of coolant conduits and the one or more branch conduits being configured to convey liquid coolant throughout the cooling system during operation to absorb heat from the plurality of computing devices and transport the coolant to the heat exchanger to dissipate the absorbed heat; and
the pair of coolant conduits are further configured to facilitate at least one of a transitional flow regime or a laminar flow regime of the liquid coolant through at least a portion of the coolant conduits.

Some embodiments relate to a system for cooling computing devices, the system including:
a plurality of open cooling tanks, each cooling tank defining an interior volume to receive computing devices and to receive a non-conductive liquid coolant;
coolant supply conduits, including a supply header conduit and a plurality of supply branch conduits, each of the supply branch conduits fluidly coupling the supply header conduit to a respective cooling tank, wherein a diameter of the supply header conduit is larger than a diameter of the supply branch conduits;
coolant return conduits, including a return header conduit and a plurality of return branch conduits, each of the return branch conduits fluidly coupling the return header conduit to a respective cooling tank, wherein a diameter of the return header conduit is larger than a diameter of the return branch conduits;
at least one heat exchanger; and
a pump system fluidly coupled to the at least one heat exchanger, the supply header conduit and the return header conduit to cause liquid coolant to flow in a closed circuit through the at least one heat exchanger and through each of the tanks simultaneously via the supply branch conduits and the return branch conduits;
wherein the coolant supply conduits are sized and configured to allow a flow rate variation of the liquid coolant of less than 10% among all of the supply branch conduits; and
wherein a first ratio of pressure loss over the supply branch conduits to pressure loss over the supply header conduit is in a first predetermined range, and
wherein a second ratio of pressure loss over the return branch conduits to pressure loss over the return header conduit is in a second predetermined range, wherein the first predetermined range is from 10:1 to 100:1.

In some embodiments, each of the supply branch conduits has a same length and same conduit diameter and each of the return branch conduits has a same length and same conduit diameter.

According to some embodiments, the coolant supply conduits are sized and configured to allow a flow rate variation of the liquid coolant of less than 5% among all of the supply branch conduits.

In some embodiments, the first predetermined range is 10:1 to 50:1. In some embodiments, the first predetermined range is 15:1 to 40:1. In some embodiments, the first predetermined range is 15:1 to 25:1.

According to some embodiments, the cooling tanks are arranged in at least one linear tank array. According to some embodiments, the supply and return header conduits extend along only one side of each at least one linear tank array.

In some embodiments, each supply branch conduit includes a flow limiting device to partially restrict flow of coolant into the respective cooling tank. According to some embodiments, the flow limiting device in each supply branch conduit includes an orifice plate. According to some embodiments, the flow limiting device in each supply branch conduit includes a ball valve. In some embodiments, the flow limiting device in each supply branch conduit is set to have a different flow limiting characteristic than each other flow limiting device. According to some embodiments, the flow limiting device that is in a supply branch conduit closest to an inlet side of the supply header conduit is set to have a highest flow limiting and the flow limiting device that is in a supply branch conduit furthest from the inlet side of the supply header conduit is set to have a lowest flow restriction.

In some embodiments, a ratio of a maximum internal diameter of the supply header conduit to a maximum internal diameter of each of the supply branch conduits is between about 2:1 and about 10:1. In some embodiments, a ratio of the maximum internal diameter of the supply header conduit to the maximum internal diameter of each of the supply branch conduits is between about 2:1 and about 4:1.

In some embodiments, a maximum internal diameter of the supply header conduit is between about 100 mm and about 500 mm. In some embodiments, a maximum internal diameter of the supply branch conduits is about 50 mm.

According to some embodiments, the liquid coolant is selected and the supply header conduit is configured so that, during operation of the system, liquid coolant flowing in the supply header conduit has a Reynolds number of between 500 and 7000.

In some embodiments, a pressure loss in the supply header conduit between a position of the supply branch conduit closest to an inlet side of the supply header conduit and the supply branch conduit furthest from the inlet side of the supply header conduit is between about 0.25 kPa and about 1 kPa. In some embodiments, a velocity pressure in the supply header conduit is between about 0.43 kPa and about 1 kPa.

Some embodiments further include a branch interconnect to selectively fluidly couple the supply branch conduit of each cooling tank to the return branch conduit of the respective tank.

In some embodiments, the diameter of the branch conduits is between 30% and 50% of the diameter of at least one of the inlet conduit and the outlet conduit.

### BRIEF DESCRIPTION OF DRAWINGS

FIG. 1 is a block diagram of a cooling system for cooling computing devices, according to some embodiments;

FIG. 2 is a schematic diagram of a cooling system for cooling computing devices, according to some embodiments;

FIG. 3 is a schematic diagram showing a detailed view of a part of the cooling system of FIG. 2, according to some embodiments;

FIG. 4 is a schematic diagram showing a detailed view of another part of the cooling system of FIG. 2, according to some embodiments;

FIG. 5 is a schematic diagram of a tank for a cooling system for cooling computing devices, according to some embodiments;

FIG. 6 is a schematic diagram of a cooling system for cooling computing devices, according to further embodiments;

FIG. 7 is a cross-section of a flange connection for a cooling system for cooling computing devices, according to some embodiments;

FIG. 8 is a focused view of part of the flange connection of FIG. 7, according to some embodiments;

FIG. 9 shows an example of a conduit end, for use in a cooling system for cooling computing devices, according to some embodiments;

FIGS. 10A and 10B show an example of a balance valve for use in a cooling system for cooling computing devices, according to some embodiments;

FIG. 11 is a schematic diagram to illustrate balance lines for use in a cooling system for cooling computing devices, according to some embodiments; and

FIG. 12 is a schematic diagram of part of the tank of FIG. 5, according to some embodiments.

### DESCRIPTION OF EMBODIMENTS

Described embodiments relate generally to systems for cooling computing devices. In various embodiments, the described systems include system components for facilitating flow of cooling fluid to tanks that store the computing devices through fluid flow tubes, pipes, valves and connectors for use in a system for cooling computing devices. The cooling fluid in embodiments described herein may be a liquid, such as an oil that is non-conductive. Systems required to constantly transport thousands of litres of liquid and that use many moving parts and/or control devices can be more prone to failure and/or be more expensive to fabricate and install. It can be difficult to maintain pressure and temperature across many cooling tanks at the same time, while avoiding too much complexity in the structure and operation of the system. Keeping the cooling fluid at a similar temperature can assist to adequately cool the computing devices while minimising the amount of energy expended. Keeping the cooling fluid at a similar pressure can assist in maintaining an even flow of the liquid to each tanks, reducing the risk of tanks overflowing or of underflowing.

Embodiments described herein are aimed at addressing problems associated with efficiently and effectively transporting non-water liquids to many cooling tanks at the same time, while keeping pressure and/or temperature in the tanks relatively consistent over time.

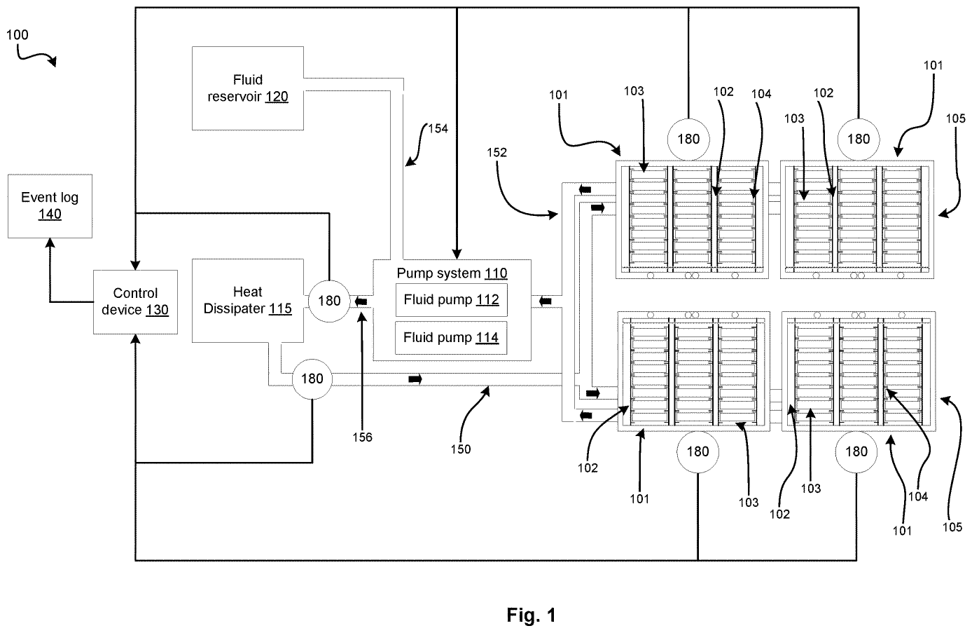

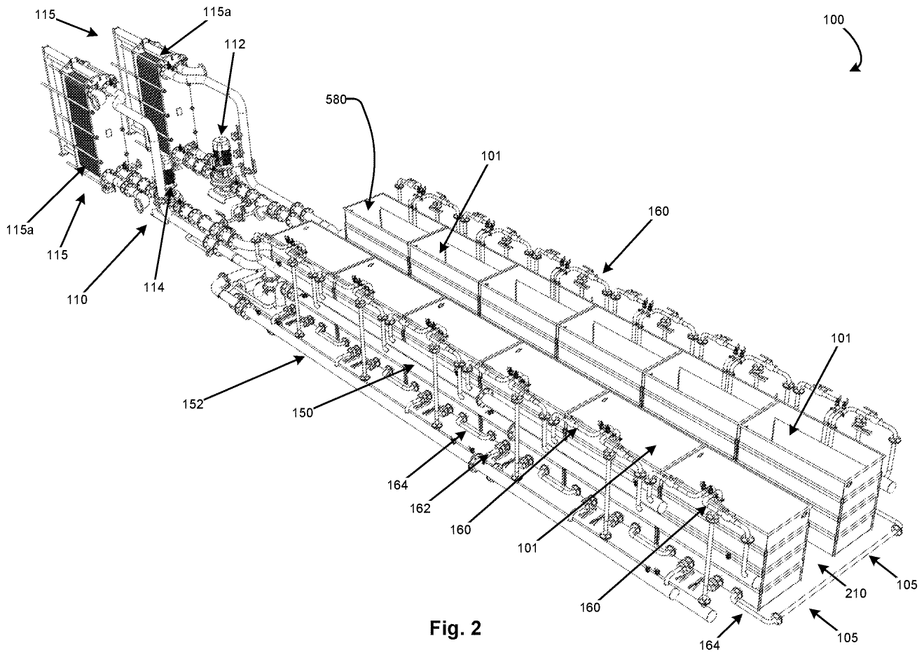

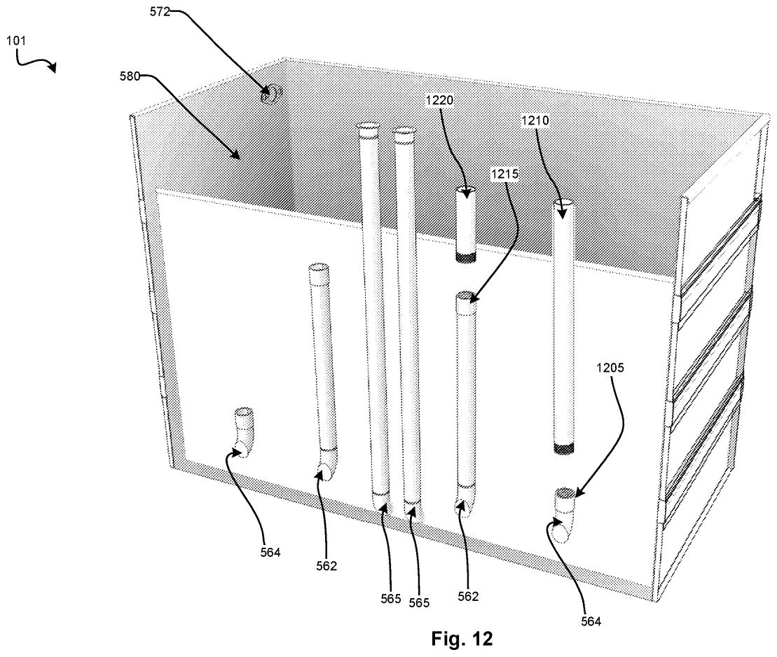

FIG. 1 is a block diagram of a cooling system 100, according to some embodiments. System 100 comprises one or more tanks 101. Tanks 101 may define an interior volume 580 (FIGS. 2, 12) to receive one or more computing devices 103 and a liquid coolant for the purpose of cooling components of the computing devices 103. System 100 may also comprise one or more pump systems 110. System 100 may also comprise one or more heat dissipaters 115. The one or more pump systems 110 operate to cause the cooling fluid to move between the tanks 101 and the one or more heat dissipators 115 within a closed circuit. Heat dissipaters 115 may be configured to receive the cooling fluid and to dissipate heat from the cooling fluid.

According to some embodiments, system 100 may be an open or non-pressurised system. In other words, tanks 101 may be open to the atmosphere, rather than sealed. Tanks 101 may nonetheless include lids or covers.

The cooling system 100 may also comprise one or more fluid reservoirs 120 to store and supply cooling fluid for transport between the tanks 101 and the heat dissipators 115. System 100 may also comprise one or more control devices 130. The system 100 may also comprise one or more event logs 140 to receive event data from the control device 130 to record performance of the system 100 over time. The system 100 is intended to be used to cool heat generating components of computing devices 103 during their operation.

Large conglomerates of computing devices such as computing devices 103 may be used to perform such operations as hosting websites, storing data, and/or engaging in computationally complex operations such as solving proof of work equations, rendering complex images and/or running large neural networks. Large numbers of computing devices operating at elevated processing speeds in close proximity generate non-negligible amounts of excess heat energy. To maintain optimal performance, these computing devices must have their excess heat energy absorbed and moved away or otherwise dissipated, lest the computing devices become damaged or thermal throttle, leading to a reduction in processing speed, resulting in lost performance and potential failure.

In existing cooling techniques, groups of computing devices may be cooled by having air moved across heat generating components, such as central processing units (CPUs), graphical processing units (GPUs), random access memory (RAM) and/or motherboard chipsets. Computing devices may also have their components cooled using a cooling liquid, such as water, routed from one heat generating component to another to form a water loop, which may be attached to a reservoir and a pumping mechanism.

An alternative cooling technique may be referred to as immersion cooling. Computing devices may be cooled by immersing the computing devices in a non-conductive liquid, such as a synthetic hydrocarbon oil. The computing devices may be submerged in this non-conductive liquid, allowing the liquid to permeate through the chassis of the computing devices, running over the heat generating components, absorbing said heat and moving it away as the liquid flows through a tank in which the computing devices are disposed.

Immersion cooling may allow for computing devices to be placed more proximal to one another when compared to other methods of cooling, such as air cooling, as the liquid may be a more effective heat sink and may be allowed to fully contact all parts of a computing device and passively absorb heat.

According to embodiments described herein, the system 100 is an immersion cooling system. System 100 may be accommodated in a smaller physical footprint compared to conglomerates of computing systems generating the same amount of heat energy, and/or having comparable combined processing capabilities that are cooled by other means, such as by air cooling. Allowing for a smaller footprint may provide for a more easily implemented modular system, that may be scaled up or down quickly, easily and in a modular fashion.

The various conduits of the system 100 may be formed from tubes, pipes and/or a combination of tubes and pipes. In the context of the present application, pipes may be hollow conduits with round cross sections, and tend to be rated for higher internal pressures and have a rougher internal surface compared to tubes. Pipes may therefore be described as high pressure conduits. In the context of the present application, tubes may be hollow conduits with a round, square, rectangular and/or oval cross section, and are generally rated to lower internal pressures than pipes, but have a smoother internal surface. Tubes may therefore be described as low pressure conduits. Accordingly, tubes may be better suited to facilitating uniform flow regimes within the system 100, and may be better for low pressure systems and systems where space and conduit configuration play a key role.

The system 100 may also be adapted and/or configured to facilitate substantially similar or identical conditions of the system coolant throughout most or all parts of system 100, or at matched, comparable or corresponding parts of system 100. In some embodiments, these conditions may be maintained at or close to the same level at substantially all times during operation. Similar or identical conditions may be the same volume of system coolant in any point of the system 100 as in any comparable point in the system 100, for example the same volume of liquid in one inlet conduit 150 and another different inlet conduit 150. Similar or identical conditions may be or include the pressure, pressure differential and/or maximum velocity pressure at any point in the system 100 as in any comparable point of the system 100. For example, it is intended that substantially the same pressure exists in one inlet conduit 150 and as in another different inlet conduit 150. When system 100 is operating within normal operational conditions, the system coolant throughout the system 100 may be considered to be in equilibrium. Similar or identical conditions may also be or include the same volume of system coolant passing through any point in the system 100 as through any comparable point of the system 100. The present disclosure may achieve this by maintaining a relatively uniform flow regime through the conduits of the system 100, through the size and configuration of the components of system 100.

In particular, system 100 may be configured to maintain a substantially equal pressure and/or flow rate of cooling fluid into each tank 101 from heat dissipater 115. This may assist to maintain a regular flow of cooling fluid through each tank 101, assisting to move the heated fluid away from the computing devices so that heat can be efficiently dissipated, while reducing the number of moving components, such as pumps and valves. This can also reduce the likelihood of the tanks 101 experiencing overflow or underflow. Overflow may occur when an excess of cooling fluid enters a single tank 101, such that the tank cannot contain the volume of cooling fluid, and the cooling fluid spills out of tank 101. Underflow may occur when there is a lack of sufficient cooling fluid entering a tank 101. This may result in the tank emptying or its liquid level dropping too much, and air being introduced into the conduits of system 100. This may also result in less heat removal from the tank, which can result in the computing devices overheating and/or operating less efficiently. The introduction of air may reduce the efficiency of the system, since air is not as thermally conductive as air.

Cooling systems configured as described in some embodiments may allow for a large quantity of cooling tanks to be connected to a single coolant distribution system, which may have just a single pump and single heat dissipater in some embodiments. When a large number of tanks are connected to a single coolant distribution system, it may be important to control the pressure and supply of coolant to each tank to avoid imbalances in the amount of coolant in the components of the system. Pipe work systems as described may therefore assist in distributing coolant evenly across multiple tanks of a system having a large quantity of cooling tanks.

To maintain substantially equal pressure and flowrate, the pipework conduits between heat dissipater 115 and each tank 101 may be arranged to provide for near identical fluid flow conditions. In other words, the structure of the pipework between heat dissipater and each tank 101 may be configured to be close to identical. This may include providing identical fittings in each pathway, identical numbers of elbows in the pipework, and/or identical branch lengths to each tank 101, so that the only difference is the position of each branch along a header. Low loss headers may be used in some embodiments. For example, some embodiments may comprise an oversized supply header conduit that reduces the effect that the position of each branch (relative to an inlet end of the supply header) has on the overall pressure drop along the length of the supply header between like points in system 100.

The disclosed embodiments may also allow for a cooling system for facilitating cooling computing devices that operates at a substantially lower range of operational pressures than other systems. A lower pressure system may enable elements of the system 100 to experience less operational strain and thereby extend their operational lifespan. A lower pressure system may also allow for the reduction in the number of complex parts such as coolant systems 110, and/or heat dissipaters 115, for example. Lower pressure systems may also allow for greater ease of service, lower failure rates and/or higher maintainability of the system 100 overall.

The tanks 101 may each be in fluidic connection (directly or indirectly) with other tanks 101, pump system 110, heat dissipater 115, and/or fluid reservoir 120 by one or more fluid conduits. Fluid conduits may include supply and return conduits, such as headers and branches, configured to allow for fluid to flow from heat dissipater 115 through each tank 101 and back to heat dissipater 115.

Tanks 101 may comprise one or more computing device racks 102 which may comprise one or more computing devices 103. The racks 102 include multiple racks spaced across the tank 101. The racks 102 are configured to receive and mount multiple rows and columns of computing devices 103 in a manner that allows cooling fluid (coolant) to flow between the computing devices 103. The racks 102 include mounting structure 104 to hold each computing device 103 in place within the tank 101.

The computing devices 103 are usually in the form of servers that are carried on or in a casing or mounting frame including a mounting substrate, such as one or more printed circuit boards (PCBs). The computing devices 103 are coupled to and/or supported by the device racks 102. The computing devices 103 are positioned in a fluid reservoir of each of the tanks 101 so as to allow coolant flowing in from a bottom section of the tank 101 to flow upward around and along the heat-generating surfaces of the computing devices 103. Coolant that has flowed past and absorbed heat from the computing devices 103 flows upward and out of the fluid reservoir of tank 101 to be pumped back through the heat dissipators 115.

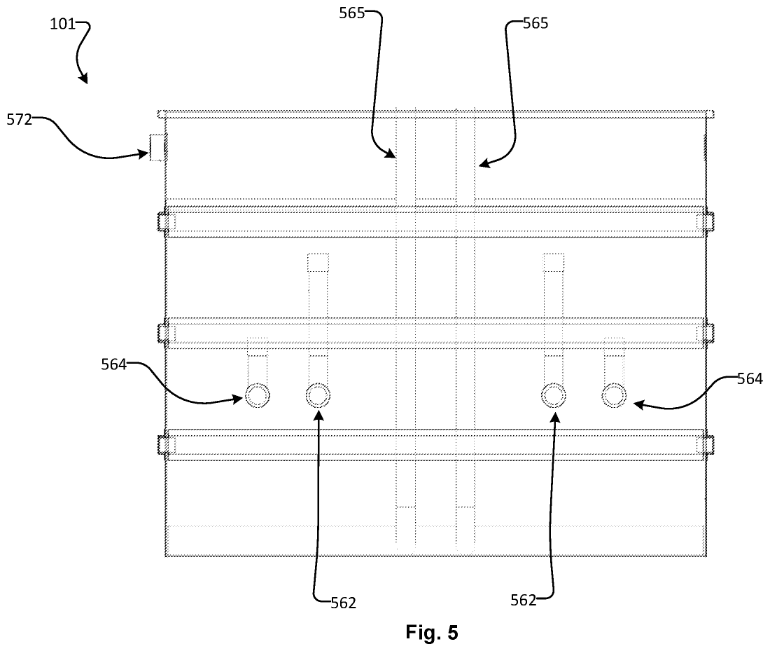

Tanks 101 may be configured into racks and/or rows 105 of tanks 101 that share common coolant supply and return conduits (as shown in FIG. 2). Each row 105 of tanks 101 includes multiple tanks arranged in a linear array. Each tank 101 may be arranged proximal (e.g., less than 0.5 metres) to at least one other tank 101. Neighbouring tanks 101 may also be fluidically connected to each other by one or more balance conduits 564 and/or one or more overflow conduits 572 (see FIG. 5). Overflow conduits 572 are positioned in an upper part of a tank side wall above a normal operating liquid level of the tank 101. This allows fluid in a first tank 101 to flow into an adjacent tank 101 via the overflow conduit 572 in case the first tank 101 would otherwise overflow.

The pump system 110 may be in fluidic communication (directly or indirectly) with heat dissipater 115, fluid reservoir 120, and/or one or more tanks 101 by one or more coolant conduits. Pump system 110 may be configured to pump system coolant throughout the system 100 to allow the coolant to collect excess heat energy from computing devices 103 in tanks 101 and dissipate it at heat dissipater 115.

In some embodiments, pump system 110 may comprise one or more fluid pumps 112, 114. Pump system 110 may comprise multiple fluid pumps 112, 114, depending on the volume of system coolant contained in system 100, and/or the number of tanks connected to system 100. Fluid pumps 112, 114 are configured to continually pump liquid oil coolant, such as a synthetic hydrocarbon oil, through the tanks 101 during normal operation (i.e., unless the system is shut down for maintenance or due to a fault). In some embodiments, fluid pump 112 may be a primary or first coolant pump and fluid pump 114 may be a secondary, back-up or second coolant pump. Fluid pump 114 may be kept at an idle rate and/or power usage, such as 50% of its full power, and be caused to ramp up to a higher rate and/or power usage upon a trigger event. A trigger event may comprise a power spike, a malfunction event, a reduction in system coolant velocity, an increase in system coolant velocity and/or any other trigger that may represent anomalous and/or non-stand behaviour of the system 100.

In some embodiments, fluid pumps 112, 114 may both be operating at 50% of their full power and both be causing the system coolant to be conveyed throughout the system and upon a trigger event, one of the fluid pumps may be caused to ramp down to a lower output, and the other fluid pump may be caused to ramp up its output to accommodate. The pumps may also be in any other configuration of reduced or increased power output relative to one another, such as 10-90, 20-80, 30-70, 40-60, for example. However, a 0-100 or 50-50 configuration may be preferred in some cases, as this may assist in facilitating the substantially even distribution of system coolant throughout the system.

In some embodiments, the system 100 may comprise multiple (2) HX-pump-pipe oil systems. The system 100 may comprise one oil pump per system, subsystem and/or parallel system, in some embodiments. In some embodiments, system 100 may comprise discrete, completely independent first (A) and second (B) cooling subsystems, optionally each with its own oil pump, for redundancy and/or back-up.

The fluid pumps 112, 114 may be sized for required capacity. In other words, as the system 100 grows in operational volume, the number of fluid pumps may not change, but their size and/or pumping capability may be scaled appropriately to the requirements of system 100. In some embodiments, the number of fluid pumps may change as system 100 is expanded in operational volume.

The heat dissipater 115 may be in fluidic connection (directly or indirectly) with pump system 110, fluid reservoir 120, and/or tanks 101 by one or more coolant conduits. Heat dissipater 115 may be configured to receive the system coolant that has absorbed excess heat generated by the computing devices 103, and to dissipate it to the surrounding environment and/or atmosphere. In some embodiments, heat dissipater 115 may be configured to first transfer the heat absorbed by the system coolant to a secondary cooling fluid, such as water, before dissipating the heat from that secondary cooling fluid to the surrounding environment and/or atmosphere. In some embodiments, heat dissipater 115 may be an adiabatic cooling system, configured to receive the system coolant, and one or more secondary coolant fluids, such as air or water.

In some embodiments, heat dissipater 115 may comprise one or more heat exchangers 115a to transfer the heat from the system coolant to a secondary cooling fluid. The heat exchanger 115a may be an oil to water interface, wherein the system coolant (e.g., oil) flowing between the tanks 101, may transfer collected heat energy to a volume of water. Each heat exchanger 115a, which may be a component of heat dissipater 115, may exchange (transfer) heat from the oil by bringing an oil-carrying conduit on a primary side of the heat exchanger 115a into close proximity with a water conduit on a secondary side of the heat exchanger 115a, to allow the heat energy within the oil to radiate to the water.

In some embodiments, the heat dissipater 115 may also comprise, either alone or in combination with other described elements, one or more of a water tower, natural water source, and/or geothermal conduit system, for example, which may be configured to transfer heat from the system 100 into the surrounding environment to cool the system coolant back down, before that coolant is fed back into coolant supply side of the system 100. In some embodiments, heat energy collected from the computing devices 103 may be repurposed, reclaimed or otherwise recycled to power additional machinery in the data centre, heat other areas of the data centre, or heat water in the data centre.

Fluid reservoir 120 may be in fluidic connection (directly or indirectly) with tanks 101, pump system 110, fluid pumps 112, 114 and/or heat dissipater 115 by one or more coolant supply conduits. Fluid reservoir 120 may be configured to collect and/or store some or all of the volume of oil within the system 100. Oil within the system 100 may be caused to be conveyed to or from the fluid reservoir 120 by fluid pump 110 and/or one or more reservoir pumps (not shown). For example, coolant may be withdrawn from the tanks 101 and coolant-circulating conduits when the system 100 or components of system 100 such as fluid pump 110, tanks 101, racks 102, computing devices 103, and/or heat dissipater 115 require maintenance, replacement and/or reconfiguration. Fluid reservoir 120 may be mechanically isolated from the rest of system 100 until oil is required to be moved to and stored in fluid reservoir 120. Fluid reservoir 120 may also be used to fill the system 100 with the system coolant for the first time or top-up coolant in the tanks 101 and coolant-circulating conduits over time. In some embodiments, fluid reservoir 120 may be or include a moveable container that may be connected or removed from the system 100 as needed.

Control device 130 may be or include one or more computing devices in communication with one or more electrical control systems (not shown) to control and monitor the operation of the system 100. The control device 130 may be in communication with one or more temperature probes 180 and/or flow sensors, to monitor temperatures and/or flow characteristics throughout the system 100. Temperature probes 180 may be installed in outlet conduit 152, return conduit 156, inside tanks 101 and/or at the inlets and/or outlets of tanks 101. In some embodiments, temperature probes 180 may be positioned proximal to the inlet and/or the outlet of heat dissipater 115.

Control device 130 may also be in communication with event log 140 to send operational notifications. In some embodiments, at predetermined times or when the control device detects conditions in system 100 that are outside of normal operating parameters, such as via one or more temperature probes 180, control device 130 may be configured to communicate a notification to event log 140. The notification may be stored in an ordered list at event log 140, tracking the performance of system 100. In some embodiments, control device 130 may also be configured to periodically, aperiodically and/or based on predetermined rules perform a system check to determine if system 100 is operating properly. Control device 130 may also continuously monitor the conditions of system 100 and provide a continuous stream of information to event log 140.

Control device 130 may also be configured to monitor the temperature of the system coolant and/or the performance of system 100. Control device 130 may be configured to read one or more temperatures of the system coolant at one or more points in system 100 and adjust the operation of one or more components of the system accordingly. For example, control device 130 may adjust the operation of a flow control device, such as one or more valves, or a fluid pump (e.g., pump 112 or 114), to increase or decrease a flowrate of a fluid through heat dissipater 115. The operational adjustment may be performed on the primary side of the heat exchanger 115a or on the secondary side of the heat exchanger 115a. For example, where increased cooling is required, the control device 130 may control a valve and/or pump (not shown) on the secondary side of the heat exchanger 115a to increase the flow rate of the secondary coolant on the secondary side of the heat exchanger 115a to provide increased heat dissipation from the system coolant, rather than to increase the flow rate of the primary coolant through the tanks 101. In some embodiments, control device 130 may also or alternatively be configured to alter the fan speed of an adiabatic system (not shown). The control device 130 may read the temperature of the system coolant using one or more temperature probes situated throughout the system 100, such as at the intake and/or outlet of the heat exchanger 115a.

FIG. 1 shows a number of system conduits, including inlet or supply conduit 150, and outlet or return conduit 152. Inlet conduit 150 and/or outlet conduit 152 may operate as header conduits. These header conduits may extend along the length of rows 105 of tanks 101. FIG. 2 also shows inlet branches 160 and outlet branches 162, as well as balance lines 164. Inlet branches 160 may connect inlet conduit 150 to tanks 101. Outlet branches may connect outlet conduit 152 to tanks 101. Balance lines 164 may connect adjacent tanks 101 to one another. These conduits are described in further detail below.

As shown in FIG. 1, heat dissipater 115 may be fluidically connected to tanks 101 by coolant inlet (supply) conduit 150, such that cooled system coolant may be supplied to tanks 101. Tanks 101 may be fluidically connected to pump system 110 via coolant outlet conduit 152, via which the heated cooling fluid exits the tanks 101. Pump system 110 may be fluidically connected with heat dissipater 115 by coolant return conduit 156, causing the heated coolant to be pumped into heat dissipater 115. In some embodiments, pump system 110 may also be in fluidic connection with fluid reservoir 120 by drain and fill pipes 154.

FIG. 2 is a schematic diagram of a cooling system 100 for cooling computing devices 103. The cooling system 100 shown in FIG. 2 may be an embodiment of the system 100 shown in FIG. 1. The cooling system 100 can be used to cool computing devices 103 operating in a data centre. The cooling system 100 comprises cooling tank(s) 101. As shown in FIG. 2, the exemplary cooling system 100 includes 12 cooling tanks 101 arranged in two rows, positioned substantially parallel to each other. In the example shown, each row includes 6 tanks 101 arranged in a linear array, although another number of tanks may be included in the row 105. Each row of tanks 101 is spaced from the other row to define an access space 210 to allow ease of inspection and access to the tank interiors. The cooling tanks 101 may be mounted or otherwise placed on a scaffold (not shown) or secured directly to the walls or floor of a housing, such as a container. In some embodiments, the system 100 may comprise more than 12 tanks 101 or fewer than 12 tanks 101. The tanks 101 may be arranged in single rows (i.e., without another adjacent row as depicted in FIG. 2), in multiple rows spaced across multiple levels (i.e. one or more upper and lower rows), and/or vertical stacks. For example, the cooling system 100 may include 16 cooling tanks 101 over two (vertically stacked) decks with 8 cooling tanks 101 on each deck.

A cooling system 100 as described with reference to FIG. 2 may be used as a sub cooling system, and another cooling system 100 may be used as another sub cooling system. The two sub cooling systems 100 can be fluidly connected together to form a larger cooling system. Such a larger cooling system including more than one sub cooling systems 100 is also described in the present disclosure.

A pipe in the present disclosure can be a straight pipe, a bent pipe, a curved pipe, or a combination of pipes in different shapes. A pipe can also include one or more segments that are fluidly connected. Further, a tube in the present disclosure may be a straight tube, a bent tube, a curved tube, or a combination of tubes in different shapes and/or configurations. The one or more segments of a pipe can extend towards the same direction or different directions. Further, the reference to the segments of a pipe is not to define the structure of the pipe, but to indicate different portions of the pipe for easy description. In some embodiments, conduit sections may be joined by a flange connection.

For ease of description, the multiple cooling tanks 101 are denoted as 101. Any cooling tank 101 may have the same structure and work in substantially the same way as any other ones of the cooling tanks 101 in the present cooling system 100. Each of the cooling tanks 101 is configured to accommodate a system coolant and is sized to immerse all or at least a portion of the computing devices 103 (not shown in FIG. 2) in the system coolant so the system coolant can absorb heat generated from the computing devices 103 so as to cool the computing devices 103.

In some embodiments, each tank 101 may be between 1000 mm and 3000 mm long. In some embodiments, each tank 101 may be between 400 mm and 2000 mm wide. In some embodiment, each tank 101 may be between 600 mm and 2000 mm tall. During normal operation, each tank 101 may be configured to hold between 1000 L and 2000 L of cooling fluid. Each tank may be configured to hold around 1400 L of cooling fluid, for example. A separation width (gap) between adjacent tanks 101 in each row 105 may be between 2 cm and 50 cm, preferably between 2 cm and 10 cm, for example.

During operation of the cooling system 100 and the data centre, one or more computing devices 103 are placed in each of the cooling tanks 101, and the heat generated from the computing devices 103 is absorbed by the system coolant in the cooling tanks 101 to reduce the temperature of the computing devices 103. As a result, the system coolant around the computing devices 103 heats up and its temperature becomes higher. The system coolant can be for example a cooling oil.

The system coolant of the present disclosures may be a type of dielectric fluid. A dielectric fluid is a non-conductive fluid that has a very high resistance to electrical breakdown events at high voltages. Electrical breakdown or dielectric breakdown is when an insulating (i.e., non-conductive) material becomes an electrical conductor. The present system may use such dielectric fluids as oils, for example synthetic oil, mineral oil or bioorganic oil, or an engineered fluid. In some embodiments, the system 100 may use a synthetic hydrocarbon oil, as synthetic hydrocarbon oils repel water and other foreign bodies.

According to some embodiments, the kinematic viscosity (KV) of the system coolant may be between 1 centistoke (cSt) and 120 cSt. In some embodiments, the kinematic viscosity of the system coolant may be between 16 cSt and 40 cSt. In some embodiments, the kinematic viscosity of the system coolant may be between 12 cSt and 20 cSt.

The cooling system 100 also comprises one or more pairs of coolant conduits, each pair of coolant conduits comprising an inlet conduit 150 and an outlet conduit 152 and providing fluidic connection between tanks 101 and heat dissipater 115. The inlet conduit 150 of each set of coolant conduits may be fluidly connected to the multiple cooling tanks 101 in a row, to supply the system coolant to the multiple cooling tanks 101. The system coolant is supplied to the tanks 101 from heat dissipater 115, after having been cooled by heat dissipater 115, via inlet conduits 150.

The inlet conduit 150 of each set of coolant conduits is fluidly connected to each of the multiple cooling tanks 101 in a row to convey the system coolant cooled by the heat dissipater 115 to each of the multiple cooling tanks 101 in the row. A single heat dissipater 115 may be connected to one or more rows of tanks 101. The system coolant carrying the heat absorbed from computing devices 103 within tanks 101 is then conveyed from each of the cooling tanks 101 via the outlet conduit 152 of each pair of coolant conduits, and the coolant returns to heat dissipater 115. The heated coolant is cooled by heat dissipater 115 and can then again be supplied to tanks 101 via inlet conduit 150.

As described above, the cooling system 100 also comprises a pump system 110 that fluidly connects to each of the inlet conduits 150 and outlet conduits 152 of each pair of coolant conduits, directly or indirectly. The pump system 110 is configured to facilitate circulation of the system coolant through the multiple cooling tanks 101, the inlet conduits 150, the outlet conduits 152, and the heat dissipater 115.

In the cooling system 100 illustrated in FIG. 2, the heat dissipater 115 fluidly connects to each of the multiple cooling tanks 101 of a row via the inlet conduits 150 and the outlet conduits 152 of each pair of coolant conduits. Further, the pump system 110 fluidly connects to each of the multiple cooling tanks 101 of a row via the outlet conduit 152 of each pair of coolant conduits. Such a structure enables a reduction in the number of pumps and/or heat dissipaters for the multiple cooling tanks 101, meaning that each tank 101 may not be required to have its own individual heat exchanger and/or its own individual coolant pump to dissipate the heat and circulate the system coolant. This is because the heat dissipater 115 and the pump system 110 are shared by the multiple cooling tanks 101. Therefore, the cooling system 100 allows a scalable deployment of the data centre. In other words, additional rows of cooling tanks 101 may be added into the cooling system 100 simply by fluidically attaching their particular inlet and outlet conduits to the system 100.

The cooling system 100 may also comprise a water supply pipe (not shown) fluidly connected to the heat exchanger 115a of heat dissipater 115 to supply water (for example, cool water) into the heat exchanger 115a in order for the heat exchanger 115 to dissipate the heat from the system coolant into the water. The cooling system 100 also comprises a water release (return) pipe (not shown) fluidly connected to an outlet of the secondary side of the heat exchanger 115a to release from the heat exchanger 115 the water with the heat (i.e., water with an elevated temperature compared to the supply water temperature).

In some embodiments, the cooling system 100 may comprise a drain and fill system. The drain and fill system may comprise coolant reservoir 120 and the drain and fill pipes 154 and may be used, for example, when the one or more cooling tanks 101 need to be drained for operational requirements and serviceability. The drain and fill system may further comprise one or more drain and fill pumps (not shown) separate from pump system 110, for conveying fluid into or out of coolant reservoir 120 via drain and fill conduit 154.

The drain and fill system is configured to drain the system coolant from one or more cooling tanks 101 and also to refill the system coolant into one or more cooling tanks 101. This way, if the one or more cooling tanks 101 need to be serviced, the drain and fill system drains the system coolant from one or more cooling tanks 101. After the service is finished, the drain and fill system fills the system coolant into the one or more cooling tanks 101. In some embodiments, system 100 may continue to convey system coolant throughout system 100 while one or more tanks 101 are emptied, serviced and refilled.

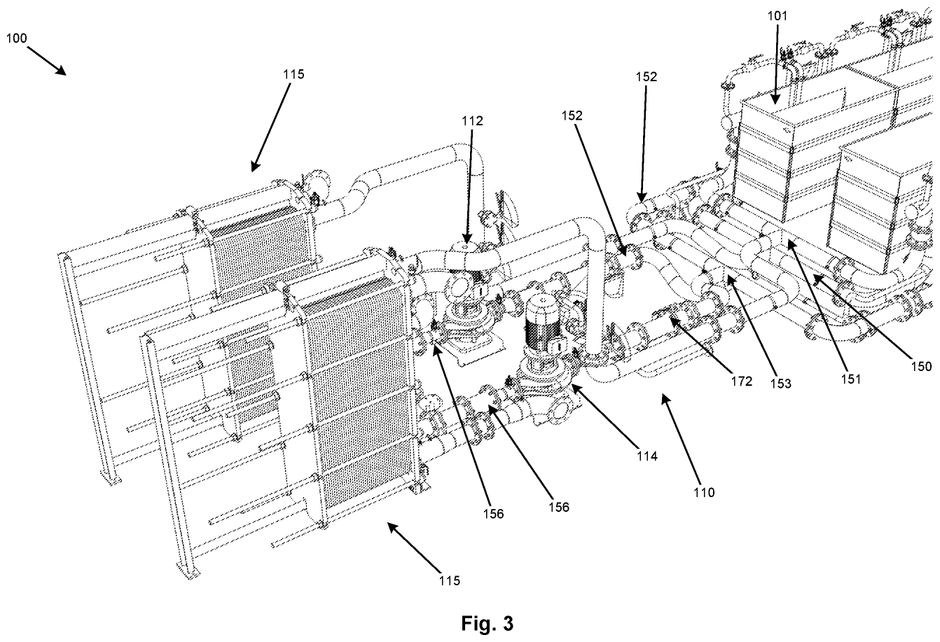

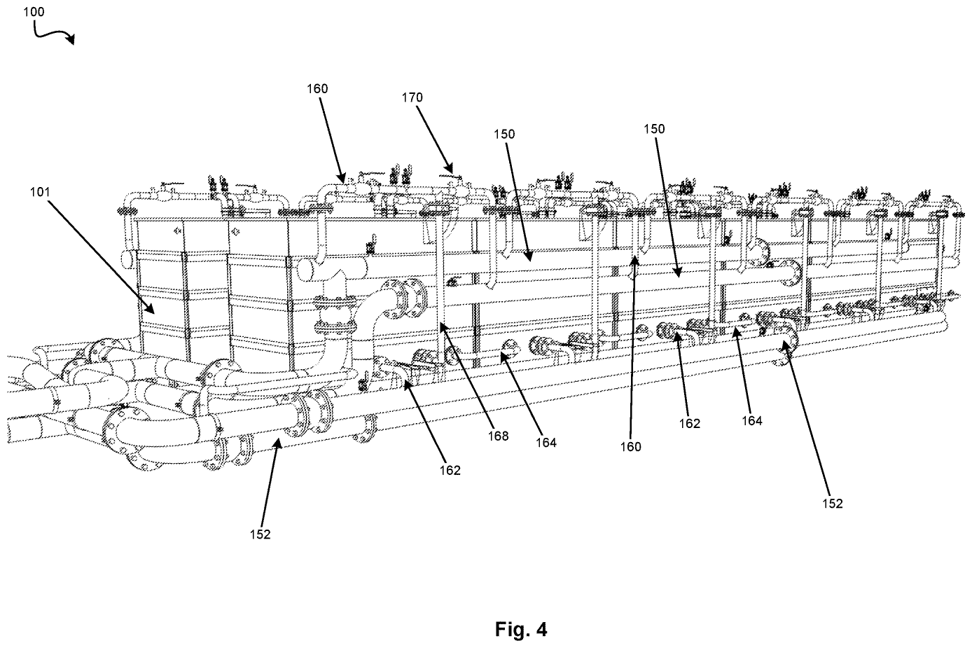

FIG. 3 and FIG. 4 are detailed schematics of cooling system 100 according to some embodiments. FIG. 3 shows the configuration of the pump system 110, heat dissipater 115, inlet conduits 150 and outlet conduits 152, among other components. FIG. 4 shows the configuration of the inlet conduits 150, outlet conduits 152, inlet branches 160 and outlet branches 162, as well as balance lines 164 and tanks 101, among other components.

During operation, system coolant may be pumped by pump system 110 through each inlet conduit 150. Each inlet conduit 150 may extend from heat dissipater 115 towards the collection of tanks 101. According to some embodiments, inlet conduit 150 may comprise one or more flow control valves, configured to restrict or block the flow of system coolant through inlet conduit 150. Proximal to tanks 101, inlet conduit 150 may reach inlet T-junction 151, which may split the supply of system coolant from inlet conduit 150 into two coolant supply conduits 150, one conduit for each row 105 of tanks 101. In some embodiments, where the system 100 only comprises one row of tanks, inlet conduit 150 may extend along the row 105 without splitting into multiple arms. In some alternative embodiments, one arm of inlet conduit 150 may terminate in a blind flange (not shown). The following description is in reference to a single row of tanks 101, and may be equally applied to an adjacent row of tanks 101 or one or more vertically stacked decks of rows of tanks 101.

According to some embodiments, inlet conduit 150 may bend around the first tank 101 in the row and may also bend upwards (towards the top of tanks 101) to run substantially parallel to the row of tanks 101. Positioning of the conduits 150, 152 and the branch conduits 160, 162 at the outside of the row of tanks may allow for the space between the two rows of tanks 101 to remain clear, which may facilitate easy access to the interior of the tanks 101 and the computing devices 103 disposed therein.

According to some embodiments, conduits 150, 152 may be positioned below a working level of the cooling fluid in the tanks 101, being the level of the fluid when system 100 is operating normally. This may reduce the risk of tanks 101 overflowing should there be a fault in system 100 that causes the fluid in conduits 150, 152 to empty.

One or more inlet branch conduits 160 may extend from inlet conduit 150, to fluidically connect inlet conduit 150 with the interiors of tanks 101, thereby allowing the system coolant to flow from heat dissipater 115 to the interior of the tanks 101. One or more outlet branch conduits 162 may extend from outlet conduit 152, to fluidically connect outlet conduit 152 with the interiors of tanks 101, thereby allowing the system coolant to flow from tanks 101 back to heat dissipater 115.

Branch conduits 160/162 may meet header conduits 150/152 at substantially a perpendicular angle. In some embodiments, branch conduits 160/162 may meet header conduits 150/152 at an obtuse angle. Branch conduits 160/162 may meet header conduits 150/152 via a long radius bend. According to some embodiments, the join between branch conduits 160/162 and header conduits 150/152 may be a pulled branch join.

In some embodiments, inlet conduits 150 and outlet conduits 152 may be configured as low loss headers to facilitate evenly distributed flow throughout the system 100. In other words, inlet conduits 150 and outlet conduits 152 may be configured such that the pressure loss along inlet conduits 150 and outlet conduits 152 is relatively low compared to other parts of the system. In some embodiments, the pressure loss through inlet conduits 150 and/or outlet conduits 152 may be substantially lower than through branch conduits 160 and/or 162.

In some embodiments, the ratio of the pressure drop through the branch conduits 160 and/or 162 to the pressure drop through the inlet conduits 150 and/or outlet conduits 152 may be maintained within a predetermined range. In some embodiments, the range may be between 5:1 to 200:1. In some embodiments, the range may be between 10:1 to 100:1 for the ratio of pressure drop across the inlet branch conduit 160 to pressure drop across the inlet conduit (supply header conduit) 150. In some embodiments, that range may be between 10:1 to 50:1. In some embodiments, that range may be between 15:1 to 40:1. In some embodiments, that range may be between 15:1 to 25:1. In some embodiments, the ratio of pressure drop across the inlet branch conduit 160 to pressure drop across the inlet conduit (supply header conduit) 150 may be maintained at around 20:1, such as between 18:1 and 22:1. In some embodiments, the pressure drop across the length of the supply branch conduits 160 may be around 20 kpa. In some embodiments, the pressure drop across the length of the return branch conduits 162 may be around 5 kPa. In some embodiments, the pressure drop across the length of the inlet conduits 150 and/or the outlet conduits 152 may be around 1 kPa.

In some embodiments, the range of ratios of pressure drop across the outlet branch conduit 162 to pressure drop across the outlet conduit (return header conduit) 152 may be between 4:1 and 15:1. In some embodiments, that range may be between 4:1 and 10:1, or between about 4:1 and about 8:1. In some embodiments, the ratio of pressure drop across the outlet (return) branch conduit 162 to pressure drop across the outlet conduit (return header conduit) 152 may be maintained at around 5:1, such as between 4:1 and 6:1.

The specific pressure drop values and ratios may be configured by selecting the size of the conduits 150, 152, 160 and 162. For example, the diameter of the conduits 150, 152 may be selected to be larger than the diameter of the branch conduits 160, 162. In some embodiments, the diameter of the conduits 150, 152 may be selected to be twice as large as the diameter of the branch conduits 160, 162. In some embodiments, the diameter of the conduits 150, 152 may be selected to be as large as practically feasible within the dimensions of system 100 to decrease the pressure drop. The diameter of the branch conduits 160, 162 may be selected to be as small as practically feasible without negatively affecting the operation of pump system 110 or substantially decreasing the flow rate through system 100.

According to some embodiments, system 100 may be configured so that branch conduits 160 and/or 162 are as well matched to one another as possible, so that each branch conduit 160 and/or 162 and any fittings coupled to the conduit 160/162 results in a substantially identical pressure drop to each other branch conduit 160/162. This may be achieved by configuring each branch conduit 160/162 to be of a substantially equal length, have substantially the same number of elbows, and/or have substantially the same number of connections to other system components. In some embodiments, branch conduits 160 may be matched to one another and branch conduits 162 may be matched to one another, but branch conduits 160 may not be matched to branch conduits 162.

According to some embodiments, the only substantial difference in the pressure and/or velocity of the fluid in each branch conduit 160/162 may be as a result of the position of the branch conduit 160/162 along conduit 150/152. The low pressure drop through conduit 160/162 as described above may be selected to minimise this difference in pressure. For example, the difference in pressure at the most proximal conduit 160/162 compared to the most distal conduit 160/162 may be maintained at less than 20% in some embodiments. In some embodiments, the difference in pressure may be maintained at less than 10%. In some embodiments, the difference in pressure may be maintained at less than 5%. In some embodiments, the variation in flow rate of the liquid coolant among the branch conduits 160/162 from one end of the tank row 105 to the other end may be maintained at less than 10%. In some embodiments, the variation in flow rate may be maintained at less than 5%.

According to some embodiments, the pressure through supply branch conduits 160 may be maintained to be more consistent between each conduit 160 than the pressure through return conduits 160. For example, the ratio of the pressure drop through the branch conduits 160 to the pressure drop through the inlet conduits 150 may be around 20:1, while the ratio of the pressure drop through the branch conduits 162 to the pressure drop through the outlet conduits 152 may be around 5:1. The velocity pressure at the return branches 162 may be maintained at less than 0.3 kPa. According to some embodiments, the pressure on the return side may be controlled less restrictively, as adding too much restriction on the suction side of pump system 110 may cause cavitation, introducing vapour into the cooling fluid and reducing the efficiency of system 100.

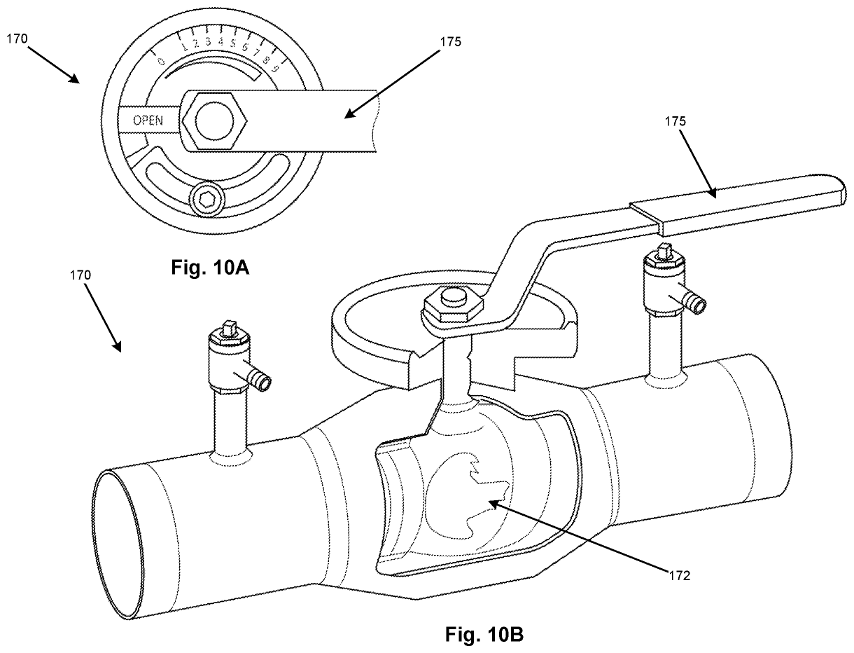

Referring now to FIG. 4, inlet branch conduits 160 may also comprise one or more balance valves 170. FIGS. 10A and 10B show an example balance valve 170 in further detail. In some embodiments, balance valves 170 may be or include a ball valve 172 configured to adjust or otherwise control the flow of system coolant into and/or out of tanks 101. Balance valves 170 may be mated to one or more tank inlet conduits such as inlet branch conduits 160, for example. The balance valves 170 may be configured to alter the amount of flow through the valve via a turning mechanism 175 such as a handle or tap, wherein the degree a valve handle or tap is turned correlates directly to the degree of flow impedance. For example, if the turning mechanism 175 is turned 50% from the open position towards the closed position, the flow of system coolant through the valve will be reduced by 50%. In another example, if the turning mechanism 175 is turned 30% from the fully open position towards the fully closed position, 30% of the coolant flow will be impeded, allowing 70% of the maximum available amount of system coolant to pass through balance valves 170. In other words, balance valves 170 may have an adjustable flow coefficient, such that adjusting the balance value 170 adjusts the quantity of fluid that flows through the valve per unit of time.

Existing balance valves, such as the kind that balance valves 170 may be produced and/or adapted from, may not be configured to integrate with the inlet branch conduits 160, as inlet branch conduits may be formed from tube segments, and existing balance valves may only be configured to interface or otherwise connect to pipe segments. Existing balance valves may also not comprise suitable valve components that would withstand exposure to the system coolant, such as the described synthetic hydrocarbon oil. Some existing balance valves may have valve components formed from rubber. Accordingly, existing balance valves must be adapted to be integrated into the system 100. For example, existing balance valves may have their rubber valve components replaced with nylon components (i.e., synthetic polymers), as nylon may be substantially more resistant to the system coolant. The plastic or rubber valve components may be one or more O-rings, disposed within the existing balance valve 170.

According to some embodiments, a different flow limiting device may be used instead of balance valves 170. For example, some embodiments may comprise orifice plates (not shown) to limit the flow of system coolant into and/or out of tanks 101. Orifice plates may be configured with different orifice sizes such that a different flow coefficient is achieved.

Flow limiting devices such as balance valves 170 and orifice plates (not shown) may be used to better equalise the pressure of the cooling fluid at branch conduits 160/162. Each flow limiting device may limit or restrict the flow to a different degree to other flow limiting devices. For example, a branch conduit 160 located close to an inlet side of inlet conduit 150 may have a higher pressure than a branch conduit 160 located further from an inlet side of inlet conduit 150. The branch conduit 160 located close to an inlet side of inlet conduit 150 may be fitted with a flow limiting device that reduces the fluid flow through the branch conduit 160 to better match the fluid flow at the more distal branch conduit 160. In other words, the branch conduit 160 located closest to an inlet side of inlet conduit 150 may have the highest flow restriction, and the branch conduit 160 located furthest from an inlet side of inlet conduit 150 may have the lowest flow restriction. According to some embodiments, the use of flow limiting devices such as balance valves 170 may be limited to avoid adding unnecessary strain to the system by requiring pump system 110 to pump harder. For example, the flow limiting devices may be used only to get the difference between the pressure (and fluid flow) at the branch conduits 160/162 below a predetermined difference threshold, such as those listed above (e.g., less than 5% or 10% difference in flow across the branches).

Referring now to FIG. 5, the system coolant is conveyed to the interior of tanks 101 via tank inlet conduits 565, which may be fluidically connected to the inlet branch conduits 160. Tank inlet conduits 565 direct the coolant to the bottom of the tank 101, where it may flow upwardly and disburse throughout the tank 101 to absorb heat from the computing devices 103 disposed within. The system coolant, once it has absorbed excess heat from the computing devices 103 and risen further up the tank 101, may be conveyed out of the tank 101 by tank outlet conduits 562, which may be fluidically connected to outlet branch conduits 162. Outlet branch conduits 162 may extend from proximal to the base of tanks 101, and fluidically connect to outlet conduit 152, which is also proximal to the base of tanks 101. Tank balance conduit 564 is fluidically connect to balance lines 164, which extend between adjacent tanks 101 to balance the level of the system coolant throughout tanks 101.

Outlet conduits 152 may extend substantially parallel to the row of tanks 101, proximal to the base of tanks 101. Outlet conduits may extend to the first tank 101 of the row of tanks 101 and connect to outlet T-junction 153. As with inlet T-junction 151, outlet T-junction 153 may join outlet conduits 152 of respective tank rows into a single outlet conduit, which extends and connects to heat dissipater 115. Outlet conduit 152 may be configured to connect with one or more of coolant pumps 112, 114, where the system coolant will be conveyed to heat dissipater 115 to shed any or some of the heat collected from computing devices 103. The system coolant may then exit heat dissipater 115 back into inlet conduit 150, ready to be recycled through the system 100 again.

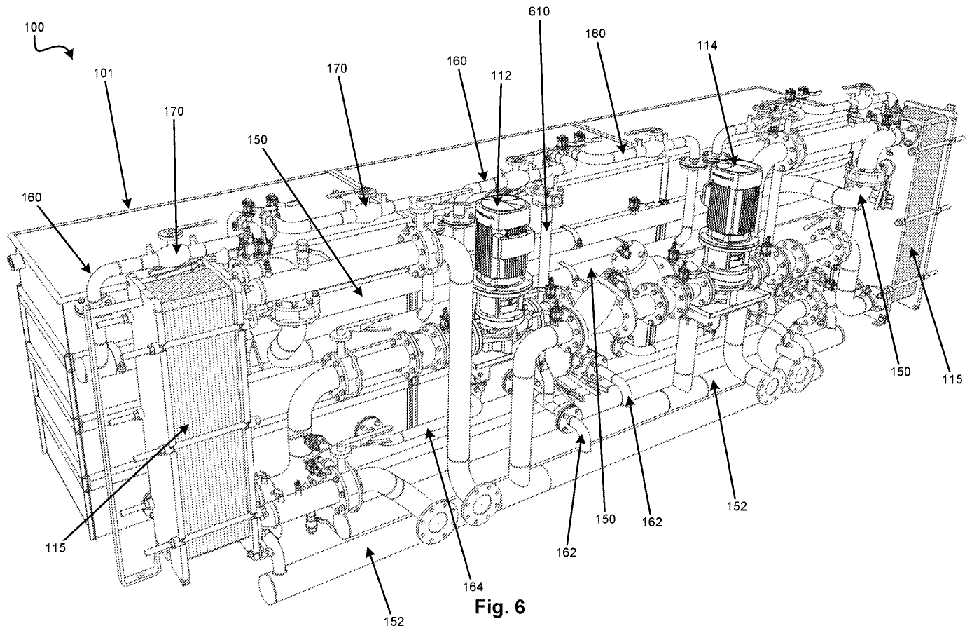

FIG. 6 is a schematic diagram of another embodiment of system 100 for cooling computing devices 103. In particular, FIG. 6 shows an embodiment of the present disclosure wherein one or more heat dissipaters 115, and one or more fluid pumps 112, 114 are disposed close to or otherwise proximal to a side or sides of tanks 101. The system as shown in FIG. 6 may occupy a smaller footprint than the system disclosed in FIGS. 2 to 4 and be configured to connect to one or more other systems of similar configuration to cool more computing devices 103 (not shown in FIG. 6). The system as disclosed in FIG. 6 may function substantially identically to the system as disclosed in FIGS. 2 to 4.

The inlet conduits 150 of FIG. 6 may be configured to extend from one or more heat dissipaters 115 disposed at an end of a row of tanks 101. Inlet conduits may extend parallel to the row of tanks 101 and comprise one or more inlet branch conduits 160. One or more inlet branch conduits 160 may extend from inlet conduit 150, to fluidically connect inlet conduit 150 with the interiors of tanks 101, thereby allowing the system coolant to flow from its source at the pump system 110 to the interior of the tanks 101. In some embodiments, inlet branch conduit 160 may be in fluidic connection with low loss header 168, which in turn is in fluidic connection with outlet conduit 152, proximal to the bases of tank 101. The system of FIG. 6 may also comprise balance valves 170, as described above.

FIG. 6 further shows a branch interconnect 610. Branch interconnect 610 may be a conduit configured to selectively fluidically connect supply branch 160 to return branch 162, to allow for a drain and fill procedure to be carried out. As described above, a drain and fill procedure may be performed to drain tanks 101, such as when maintenance is to be performed, and to subsequently refill the tanks 101. As described above with reference to FIG. 5, tank inlet conduits 565 are configured to direct the coolant to the bottom of the tank 101, and so may be positioned to open into the base or near the base of tanks 101. Tank outlet conduits 562 are configured to receive coolant from further up the tank 101, and so open into tank 101 at a higher level, which may be at around half to three-quarters of the way up the height of tank 101. As a result, if tank outlet conduits 562 are used to empty tank 101, a significant amount of coolant may remain within tank 101. To overcome this, branch interconnect 610 may be used, to allow tank inlet conduits 565 to be connected to return branch 162 such that tank inlet conduits 565 can be used to drain tanks 101. As tank inlet conduits 565 are located close to the base of tanks 101, draining the coolant from tanks 101 via tank inlet conduits 565 results in less coolant remaining in tanks 101 after draining. Isolation valves may be used to isolate tank inlet conduits 565 from inlet conduit 150 during such a procedure.

Outlet conduits 152 may extend substantially parallel to the row of tanks 101, proximal to the base of tanks 101. The outlet conduits 152 may be configured to connect with one or more of coolant pumps 112, 114, where the system coolant will be conveyed to heat dissipater 115 to shed any heat collected from computing devices 103. The system coolant may then exit heat dissipater 115, ready to be recycled through the system 100 again.

The present systems may be configured to encourage the development, and maintenance of optimal flow conditions within the conduits of the disclosed systems, and maintain an even distribution of system coolant throughout the tanks and conduits during operation, regardless of the number of tanks 101 in the system 100. The fluid may be conveyed through the conduits in one or more fluid flow states. The flow states may be one or more of turbulent flow, transitional flow and/or laminar flow. Turbulent flow may be when the regime of the flow comprises irregular random motion of fluid particles in directions transverse to the direction on main flow. Laminar flow may be when the regime of the flow comprises straight parallel motion of fluid particles relative to the walls of the conduit. Transitional flow may comprise characteristics of both turbulent and laminar flow. Flow states may be measured by the Reynolds number, as calculated using the equation

$${R}_{e} = \frac{ρ uL}{μ} ,$$

where Rₑ is Reynolds number, ρ is fluid density, u is flow speed, L is characteristic length of the system 100 and μ is the dynamic viscosity of the fluid. A Reynolds number of less than 2,300 may indicate laminar flow, a Reynolds number between 2,300 and 4,000 may indicate transitional flow and a Reynolds number of greater than 4,000 may indicate turbulent flow. In some embodiments, the described systems may be configured to maintain transitional flow throughout a substantial portion of the various conduits 150, 152, 160, 162. In some embodiments, the described systems may be configured to avoid transitional flow through the various conduits 150, 152, 160, 162, and to instead maintain either laminar or turbulent flow. According to some embodiments, turbulent flow may provide for better heat transfer than laminar or transitional flow. In some embodiments, the liquid coolant is selected and the supply header conduit 152 is configured (including being sized) so that, during operation of the system 100, liquid coolant flowing in the supply header conduit has a Reynolds number of between 500 and 7000. However, across system 100, the Reynolds number may vary between 500 and 20,000.

In some embodiments, uniform system coolant distribution and or flow regime may be encouraged and/or maintained by the sizing and/or configuration of the various conduits that the system coolant is conveyed through. The system 100 may encourage system coolant to flow from the inlet conduits 150 to the inlet branch conduits 160, from outlet branch conduits 162 to outlet conduits 152 and/or from any one or more connected conduits of the system 100 by maintaining particular flow rates, differential pressures and/or maximum velocity pressures in each of the particular conduits of the system 100. Differential pressure may refer to the pressure difference between the pressures at each end of a conduit, or the pressure loss in that conduit.

For example, in some embodiments, the inlet conduits 150 may have an internal diameter of between 100 mm and 500 mm. In some embodiments, the inlet conduits 150 may have an internal diameter of about 150 mm. In some embodiments, the inlet conduits 150 may have an average and/or median flow rate of about 16 litres per second. In some embodiments, the inlet conduits 150 may have an average and/or median differential pressure of less than 1 kPa and/or a maximum velocity pressure of less than 1 kPa. In some embodiments the inlet conduits 150 may have an internal diameter of about 100 mm. In some embodiments, the inlet conduits 150 may have an average and/or median flow rate of about 9 litres per second. In some embodiments, the inlet conduits 150 may have an average and/or median differential pressure of between 0.60 kPa and 1 kPa and/or a maximum velocity pressure of between 0.43 kPa and 1 kPa. In some embodiments the inlet conduits 150 may have an average and/or median differential pressure of between 0.25 kPa and 1 kPa and/or a maximum velocity pressure of between 0.53 kPa and 1 kPa. In some embodiments, the inlet conduits 150 may have an average and/or median differential pressure of about 0.60 kPa and/or a maximum velocity pressure of about 0.43 kPa and 1 kPa. In some embodiments the inlet conduits 150 may have an average and/or median differential pressure of about 0.25 kPa and/or a maximum velocity pressure of about 0.53 kPa.

In some embodiments, the outlet conduits 152 may have an internal diameter of between 100 mm and 500 mm. In some embodiments, the inlet conduits 150 may have an internal diameter of about 150 mm. In some embodiments, the outlet conduits 152 may have an average and/or median flow rate of about 16 litres per second. In some embodiments, the outlet conduits 152 may have an average and/or median differential pressure of less than 1 kPa and/or a maximum velocity pressure of less than 0.5 kPa. In some embodiments, the outlet conduits 152 may have an internal diameter of about 100 mm. In some embodiments, the outlet conduits 152 may have an average and/or median flow rate of about 9 litres per second. In some embodiments, the outlet conduits 152 may have an average and/or median differential pressure of less than 1 kPa and/or a maximum velocity pressure of less than 0.5 kPa. In some embodiments, the outlet conduits 152 may have an average and/or median differential pressure of between 0.2 and 1 kPa and/or a maximum velocity pressure of between 0.42 kPa. In some embodiments, the outlet conduits 152 may have an average and/or median differential pressure of between 0.18 kPa and 1 kPa and/or a maximum velocity pressure of between 0.2 kPa and 0.5 kPa. In some embodiments, the outlet conduits 152 may have an average and/or median differential pressure of about 0.2 kPa and/or a maximum velocity pressure of about 0.42 kPa. In some embodiments, the outlet conduits 152 may have an average and/or median differential pressure of about 0.18 kPa and/or a maximum velocity pressure of about 0.2 kPa.

In some embodiments, the inlet branch conduits 160 may have an internal diameter of about 50 mm. In some embodiments, the inlet branch conduits 160 may have an average and/or median flow rate of about 2.6 litres per second to 3 litres per second, and/or an average and/or median differential pressure of greater than 15 kPa. In some embodiments, the inlet branch conduits 160 may have an average and/or median flow rate of about 2.6 litres per second to 3 litres per second, and/or an average and/or median differential pressure of between 21 kPa to 15 kPa. In some embodiments, the inlet branch conduits 160 may have an average and/or median flow rate of about 2.6 litres per second to 3 litres per second, and/or an average and/or median differential pressure of about 21 kPa.

In some embodiments, the outlet branch conduits 162 may have an internal diameter of about 50 mm. In some embodiments, the outlet branch conduits 162 may have an average and/or median flow rate of about 2.6 litres per second to 3 litres per second, and/or an average and/or median differential pressure of greater than 2.4 kPa. In some embodiments, the outlet branch conduits 162 may have an average and/or median flow rate of about 2.6 litres per second to 3 litres per second, and/or an average and/or median differential pressure of between 2.8 kPa and 2.4 kPa. In some embodiments, the outlet branch conduits 162 may have an average and/or median flow rate of about 2.6 litres per second to 3 litres per second, and/or an average and/or median differential pressure of about 2.8 kPa.

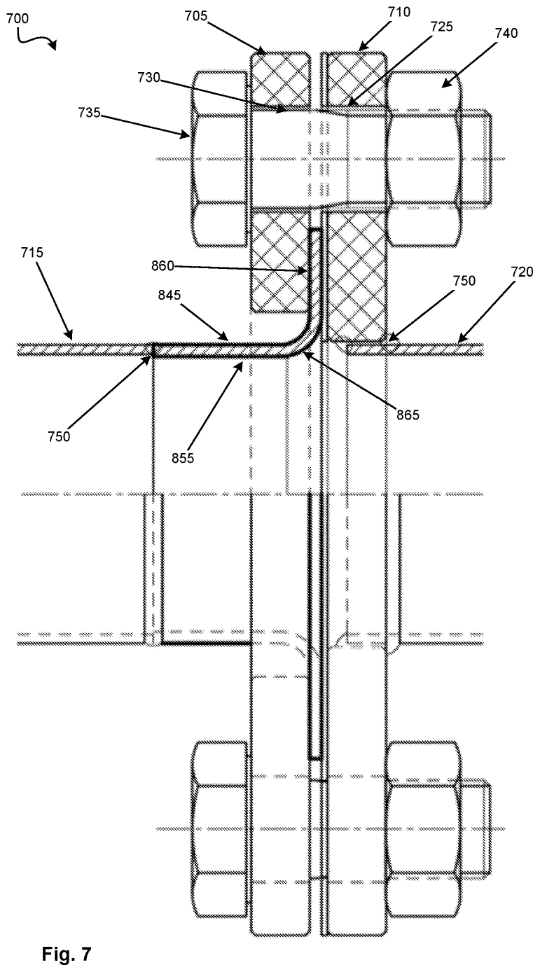

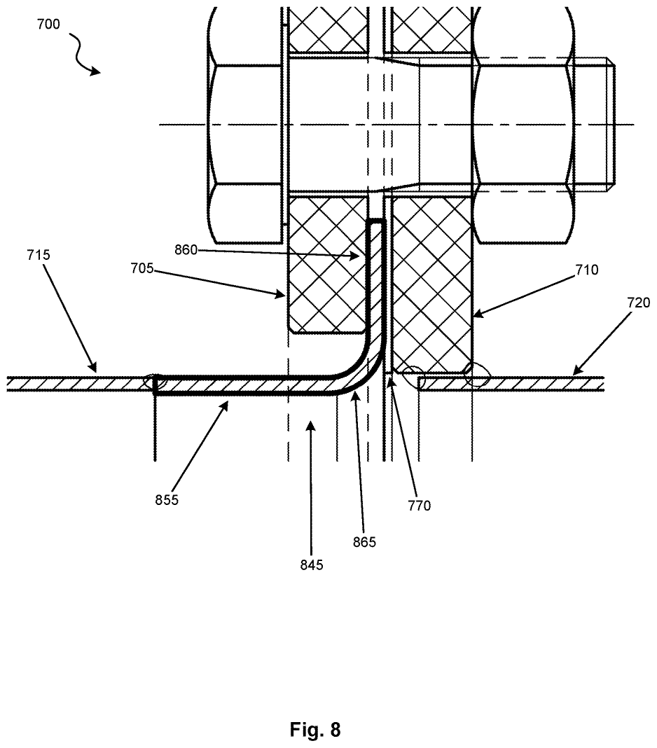

In some embodiments, the internal diameter of the inlet branch conduits 160 and/or outlet branch conduits 162 may be between 30% and 50% of the internal diameter of the inlet conduits 150 and/or the outlet conduits 152. In some embodiments, the internal diameter of the inlet branch conduits 160 and/or outlet branch conduits 162 may be approximately 30% of the internal diameter of the inlet conduits 150 and/or the outlet conduits 152. The internal diameter of inlet branch conduits 160 may be approximately 50% of the internal diameter of the inlet conduits 150, in some embodiments. In some embodiments, the internal diameter of the outlet branch conduits 162 may be approximately 40% of the internal diameter of outlet conduit 152. In some embodiments, the ratio between the internal diameter of the inlet conduits 150 and/or the outlet conduits 152 to the internal diameter of the inlet branch conduits 160 and/or outlet branch conduits 162 may be between 2:1 and 10:1. In some embodiments, the ratio between the internal diameter of the inlet conduits 150 and/or the outlet conduits 152 to the internal diameter of the inlet branch conduits 160 and/or outlet branch conduits 162 may be between 2:1 and 4:1. FIG. 7 and FIG. 8 are cross-sectional schematics of a flange connection 700 for a cooling system for cooling computing devices 103, according to some embodiments. FIG. 7 is a cross-sectional schematic of the flange connection 700, according to some embodiments. FIG. 8 shows a focused view of the cross-sectional schematic of FIG. 7.

Flange connection 700 may comprise first plate member 705, second plate member 710, first conduit 715, and second conduit 720. First conduit 715 may be configured to be captured between first plate member 705 and second plate member 710 such that when first plate member 705 and second plate member 705 are drawn together, for example via a fastening force, first conduit 715 and second conduit 720 are caused to be fluidically connected.

First plate member 705 may define a plurality of apertures. In some embodiments first plate member 705 may define one or more first fastening apertures 730, and/or conduit aperture 745. As exemplified in FIG. 8, the first fastening apertures 730 may be configured to receive bolt 735, for securing first flange plate 705 with second flange plate 710, when bolt 735 engages with nut 740 through second fastening aperture 725. Conduit aperture 745 may be configured to receive first conduit 715. In some embodiments, conduit aperture 745 may be a clearance fit around first conduit 715, allowing for the sliding and/or rotation of the first flange plate 705, to allow for ease of aligning first fastening apertures 730 with corresponding second fastening apertures 725 of second flange plate 710. In some embodiments, second flange plate 710 may be non-removably affixed to second conduit 720, such as by welded portions 750.

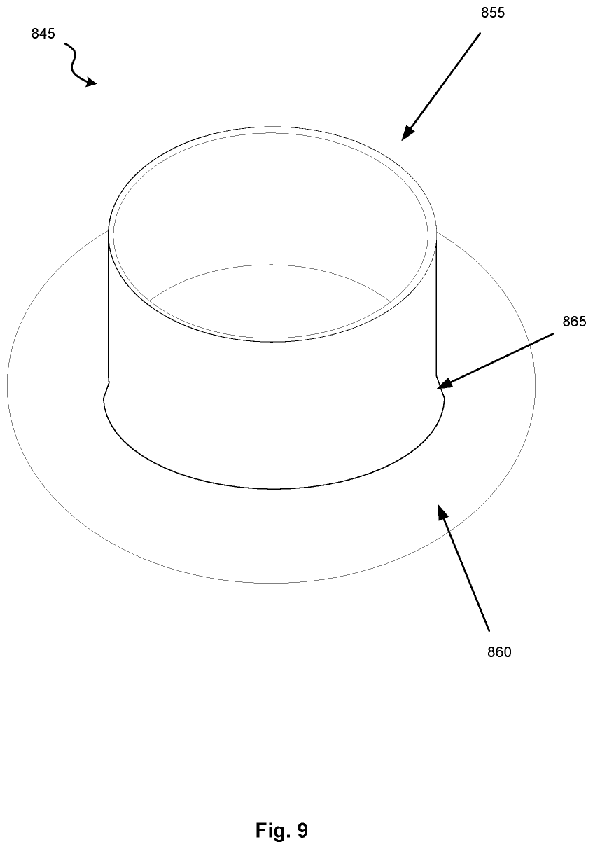

End portion 845 is shown in further detail in FIG. 9. End portion 845 may be non-removably affixed to first conduit 715, such as via welded portions 750. End portion 845 may comprise fastening portion 855, sealing portion 860 and bend 865. End portion 845 may be formed from a single piece, such as a stainless steel pipe or tube or a stainless steel disc, and may have uniform wall thickness. Fastening portion 855 may be connected to sealing portion 860 via bend 865. Sealing portion 860 may be configured to be captured between first flange plate 705 and second flange plate 710, so as to form a fluidic connection between first conduit 715 and second conduit 720.

In some embodiments, end portion 845 may be formed, for example, from a portion of pipe, tube or a stainless steel disc, by a metal shaping process, such as metal spinning or form pressing. In some embodiments, to form end portion 845, a disc (not shown) may be cut from a sheet of stainless steel (not shown), the cutting of the disc may comprise cutting or otherwise forming a central hole in the disc. The central hole may also be formed after the disc has already been cut. To form the end portion 845 from the disc, a mandrel (not shown), or other style of forming die, may be passed through the central hole formed in the disc. The mandrel may be in substantially similar shape to the formed end portion 845. The disc may be held stationary while abutting the mandrel as the mandrel is spun, forming end portion 845. In some embodiments, a roller may be used to press or otherwise form the disc around the shape of mandrel, thereby contouring the disc to the same shape as the mandrel.

In some embodiments, when end portion 845 is formed from a single piece, fastening portion 855 and sealing portion 860 may be connected by bend 865. Bend 865 may be configured such that fastening portion 855 and sealing portion 860 are substantially perpendicular to each other. Bend 865 may have a bend radius of 2 mm.

In some embodiments, sealing member 770 may be positioned between sealing portion 860 of end portion 845, and second flange plate 710. Sealing member 770 may be formed from rubber, silicone, metal, cork, felt, neoprene, nitrile rubber, fiberglass, polytetrafluoroethylene or a plastic polymer, for example. When compressed between end portion 745 and second flange plate 710, due to the fastening forcing between first flange plate 705 and second flange plate 710, sealing member 770 may expand to substantially fill gaps in the fastening surfaces, creating a fluidic or otherwise watertight connection between first conduit 715 and second conduit 720. Sealing member 770 may be an O-ring or a gasket. In some embodiments, second conduit 720 also comprises an end portion, similar to that of first conduit 715, as described above. In this embodiment, both end portions may be configured to receive a gasket or O-ring between their respective sealing portions 860. In some embodiments, a baffle plate (not shown), may be positioned between sealing portion 860 and second flange plate 710. The baffle plate may comprise a plurality of openings which are configured to restrain and/or regulate the flow of the system coolant through the conduit.

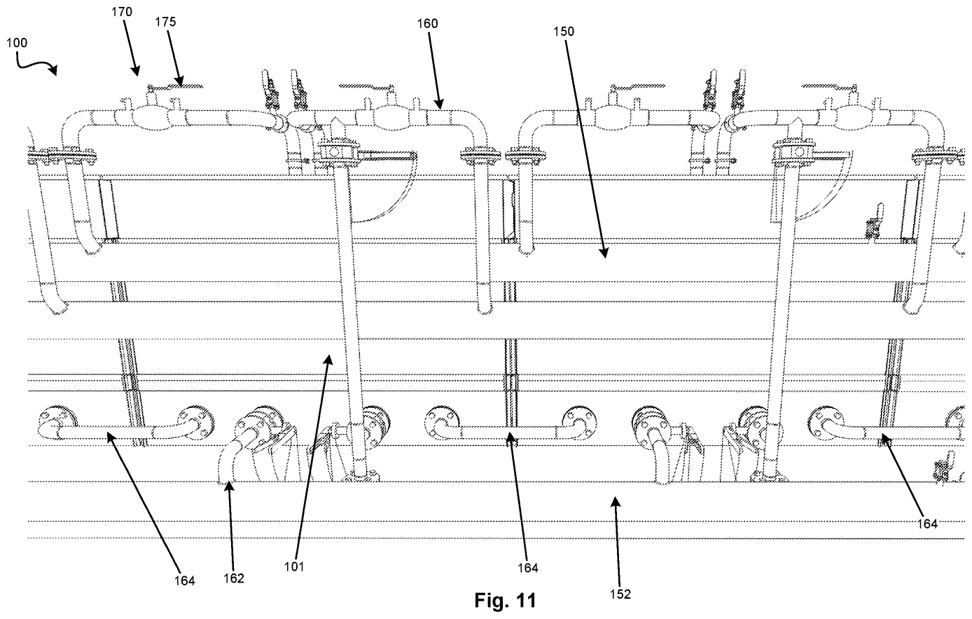

FIGS. 11 and 12 show aspects of system 100 that may allow for the fluidic isolation of one or more tanks 101 to allow for replacement or repair of the tanks 101 or components housed by tanks 101.

FIG. 11 shows a detailed view of a side of a tank 101. As described above, particularly with reference to FIGS. 5, 10A and 10B, inlet branch conduits 160 may comprise one or more balance valves 170. Balance valves 170 may be configured to adjust or otherwise control the flow of system coolant into and/or out of tanks 101. The balance valves 170 may be configured to alter the amount of flow through the valve via a turning mechanism 175, which may be a handle or tap in some embodiments. The degree that the turning mechanism 175 is turned may correlates directly to the degree of flow impedance. For example, if the turning mechanism 175 is turned 50% from the open position towards the closed position, the flow of system coolant through the valve will be reduced by 50%. In another example, if the turning mechanism 175 is turned 30% from the open position towards the closed position, 30% of the flow will be impeded, allowing 70% of the system coolant to pass through balance valves 170.

Tanks 101 may also comprise balance lines 164 running between adjacent tanks 101 for facilitating the levelling of system coolant throughout tanks 101. Specifically, balance lines 164 may facilitate the levelling of system coolant throughout tanks 101 that are located on an equal level. Balance lines 164 may be in fluidic connection with tank balance conduits 564, as shown in FIG. 5.

FIG. 12 shows the inside of a tank 101 having tank inlet conduits 565, tank outlet conduits 562 and tank balance conduits 564. Tank balance conduits 564 may extend from a location near the base of tank 101 to a location at least part way up the tank 101 at which each tank balance conduit 564 may have an open end 1205, (e.g. a threaded end) such that any system coolant above the open end 1205 of the tank balance conduit 564 may be free to enter and exit tank balance conduit 564 to facilitate the balancing of system coolant across multiple tanks 101 in system 100.

Tank outlet conduits 562 may extend from a location near the base of tank 101 to a location at least part way up the tank 101 at which each tank inlet conduit 562 may have an open end 1215, such that any system coolant above the open end 1215 may be free to enter tank outlet conduit 562.

In order to fluidically isolate a tank from connecting tanks, a closing member 1210 or 1220 may be couplable to an open end 1205 and/or 1215 of each tank balance conduit 564 and tank outlet conduit 562. According to some embodiments, closing member 1210 and/or 1220 may be a plug. In some embodiments, closing member 1210 and/or 1220 may be threaded to screw into the open end 1205 or 1215. According to some embodiments, closing member 1210 and/or 1220 may be a pipe section of sufficient length such that an open end of the pipe section is above the level of liquid coolant in tank 101 when the closing member is in place coupled to the open end 1205 or 1215 of tank outlet conduit 562 or tank balance conduit 564.

Once located in the open end 1205, closing member 1210 may provide a seal that fluidically isolates balance conduit 564 and therefore balance line 164 from the interior volume 580 of tank 101. Tank 101 can then be drained via tank inlet conduits 565 and/or tank outlet conduits 562, and removed, replaced or repaired as necessary.

Similarly, once located in the open end 1215, closing member 220 may provide a seal that fluidically isolates tank outlet conduit 562 and therefore branch outlet conduit 162 from the interior volume 580 of tank 101. Tank 101 can then be drained via tank inlet conduits 565 and/or balance conduits 564, and removed, replaced or repaired as necessary.

In some embodiments, the cooling system for cooling computing devices 100 may implement technology as described in International Patent Application no. PCT/AU2021/051215, the contents of which are hereby incorporated by reference.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1.-37. (canceled)

38. A cooling system for facilitating cooling of computing devices, the cooling system comprising:
one or more mounting racks;
a plurality of cooling tanks arranged into one or more rows, configured to accommodate a liquid coolant and sized to immerse a plurality of computing devices in the liquid coolant when the liquid coolant is located in the tanks in order for the liquid coolant to absorb heat generated from the computing devices, wherein the plurality of cooling tanks are affixed to the one or more mounting racks, each cooling tank being arranged proximal to at least one other cooling tank;
a heat dissipater configured to receive the liquid coolant carrying the heat absorbed from the computing devices and to dissipate heat from the liquid coolant;
a coolant pump configured to facilitate circulation of the liquid coolant through the cooling system; and
a pair of coolant conduits, wherein the pair of coolant conduits comprise an inlet conduit and an outlet conduit and extend substantially along a length of one row of cooling tanks and proximal to a base of the cooling tanks, and wherein the pair of coolant conduits are in fluidic communication with the heat dissipater and the coolant pump, wherein the inlet conduit and the outlet conduit are configured as low loss headers to facilitate evenly distributed liquid flow through the cooling system;
one or more branch conduits in fluidic connection with the plurality of cooling tanks and the pair of coolant conduits and configured to convey the liquid coolant into and out of the plurality of cooling tanks;
wherein the branch conduits comprise at least one inlet branch conduit configured to direct the liquid coolant to a bottom of a corresponding tank and at least one outlet branch conduit configured to convey liquid coolant out of the corresponding tank from above the inlet branch conduit;
wherein the pair of coolant conduits and the one or more branch conduits are configured to convey liquid coolant throughout the cooling system during operation to absorb heat from the plurality of computing devices and to transport the coolant to the heat dissipater to dissipate the absorbed heat;
wherein the pair of coolant conduits and the one or more branch conduits are further configured to facilitate at least one of a transitional flow regime or a laminar flow regime of the liquid coolant through at least a portion of the cooling system;
wherein the plurality of cooling tanks include a first tank and a second tank, and wherein the first tank and the second tank comprise:
a balance line in fluidic connection with a first balance conduit of the first tank and a second balance conduit of the second tank, wherein the balance line is configured to balance a volume of liquid coolant within the first tank and the second tank during operation.

39. The cooling system of claim 38, wherein the coolant conduits have an internal diameter of between about 100 mm and about 150 mm and wherein the branch conduits have an internal diameter of about 50 mm.

40. The cooling system of claim 38, wherein the cooling system is configured to maintain:
a differential pressure of less than 1 kPa and a maximum velocity pressure of less than 1 Kpa in the inlet conduit;
a differential pressure of less than 1 kPa and a maximum velocity pressure of less than 0.5 kPa in the outlet conduit;
a differential pressure of greater than 15 kPa in the at least one inlet branch conduit;
a differential pressure of greater than 2.4 kPa in the at least one outlet branch conduit.

41. The cooling system of claim 38, wherein the coolant pump, the coolant conduits and the branch conduits are configured to maintain a flowrate of between 9 L/s and 16 L/s within the inlet conduit and the outlet conduit and a flowrate of between 2.6 L/s and 3 L/s in the one or more branch conduits.

42. The cooling system of claim 38, comprising a first set of coolant conduits and a second set of coolant conduits, and wherein the one or more branch conduits are a first set of branch conduits and the cooling system further comprises a second set of branch conduits;
wherein the second set of coolant conduits and the second set of branch conduits are part of a parallel tank cooling system.

43. The cooling system of claim 38, wherein an average flow regime of the cooling system has a Reynolds number of between 2,300 and 4,000.

44. A cooling system for facilitating cooling of computing devices according to claim 38, wherein the cooling system comprises:
one or more balance valves, the one or more balance valves being in fluidic communication with one or more branch conduits, respectively, each balance valve comprising:
an inlet conduit and an outlet conduit, wherein the inlet and outlet conduits are adapted to interface with the branch conduit;
one or more synthetic polymer O-rings;
an actuating handle; and
a flow control member, the flow control member being rotatable by the actuating handle;
wherein when the flow control member is rotated by the actuating handle, the flow control member is configured to restrict the flow of coolant through the balance valve by a percentage that is related to the percentage rotation of the actuating handle.

45. The cooling system of claim 38, wherein
the first tank comprises a first inlet conduit and the first balance conduit and the second tank comprises a second inlet conduit and the second balance conduit, each of the first and second inlet conduits and the first and second balance conduits is configured to receive an isolating member, wherein when an isolating member is received by the inlet conduit and the balance conduit of the first tank, and when an isolating member is received by the inlet conduit and the outlet conduit of the second tank, at least the first tank is caused to be fluidically disconnected from the cooling system.

46. A cooling system for facilitating cooling of computing devices, the cooling system comprising:
a plurality of cooling tanks arranged into one or more row(s), each tank configured to accommodate a liquid coolant and sized to immerse a plurality of computing devices in the liquid coolant when the liquid coolant is located in the tanks in order for the liquid coolant to absorb heat generated from the computing devices;
wherein each of the plurality of cooling tanks are arranged proximal to at least one other cooling tank;
a heat dissipater configured to receive the liquid coolant carrying the heat absorbed from the computing devices to dissipate the heat from the liquid coolant;
a pair of coolant conduits, the pair of coolant conduits comprising an inlet conduit and an outlet conduit, and each row of coolant tanks comprising at least one pair of coolant conduits extending substantially along a length of the row and proximal to a base of the cooling tanks, and the pair of coolant conduits being in fluidic communication with the heat dissipater, wherein the inlet conduit and the outlet conduit of each pair of coolant conduits are configured as low loss headers to facilitate evenly distributed liquid flow through the cooling system;
one or more branch conduits in fluidic connection with the plurality of cooling tanks and the pair of coolant conduits, the branch conduits being configured to convey the liquid coolant between the coolant tanks and the coolant conduits;
wherein the branch conduits comprise at least one inlet branch conduit configured to direct the liquid coolant to a bottom of a corresponding tank and at least one outlet branch conduit configured to convey liquid coolant out of the corresponding tank from above the inlet branch conduit;
the one or more pairs of coolant conduits and the one or more branch conduits being configured to convey liquid coolant throughout the cooling system during operation to absorb heat from the plurality of computing devices and transport the coolant to the heat dissipater to dissipate the absorbed heat; and
the pair of coolant conduits are further configured to facilitate at least one of a transitional flow regime or a laminar flow regime of the liquid coolant through at least a portion of the coolant conduits;
wherein the plurality of cooling tanks include a first tank and a second tank, and wherein the first tank and the second tank comprise:
a balance line in fluidic connection with a first balance conduit of the first tank and a second balance conduit of the second tank, wherein the balance line is configured to balance a volume of liquid coolant within the first tank and the second tank during operation.

47. A system for cooling computing devices, the system including:
a plurality of open cooling tanks, each cooling tank defining an interior volume to receive computing devices and to receive a non-conductive liquid coolant;
coolant supply conduits, including a supply header conduit and a plurality of supply branch conduits, each of the supply branch conduits fluidly coupling the supply header conduit to a respective cooling tank, wherein a diameter of the supply header conduit is larger than a diameter of the supply branch conduits;
coolant return conduits, including a return header conduit and a plurality of return branch conduits, each of the return branch conduits fluidly coupling the return header conduit to a respective cooling tank, wherein a diameter of the return header conduit is larger than a diameter of the return branch conduits;
at least one heat exchanger; and
a pump system fluidly coupled to the at least one heat exchanger, the supply header conduit and the return header conduit to cause liquid coolant to flow in a closed circuit through the at least one heat exchanger and through each of the tanks simultaneously via the supply branch conduits and the return branch conduits;
wherein the coolant supply conduits are sized and configured to allow a flow rate variation of the liquid coolant of less than 10% among all of the supply branch conduits; and
wherein a first ratio of pressure loss over the supply branch conduits to pressure loss over the supply header conduit is in a first predetermined range, and wherein a second ratio of pressure loss over the return branch conduits to pressure loss over the return header conduit is in a second predetermined range, wherein the first predetermined range is from 10:1 to 100:1.

48. The system of claim 47, wherein each of the supply branch conduits has a same length and same conduit diameter and each of the return branch conduits has a same length and same conduit diameter.

49. The system of claim 47, wherein the coolant supply conduits are sized and configured to allow a flow rate variation of the liquid coolant of less than 5% among all of the supply branch conduits.

50. The system of claim 47, wherein the cooling tanks are arranged in at least one linear tank array.

51. The system of claim 47, wherein the supply and return header conduits extend along only one side of each at least one linear tank array.

52. The system of claim 47, wherein each supply branch conduit includes a flow limiting device to partially restrict flow of coolant into the respective cooling tank and wherein the flow limiting device that is in a supply branch conduit closest to an inlet side of the supply header conduit is set to have a highest flow limiting and the flow limiting device that is in a supply branch conduit furthest from the inlet side of the supply header conduit is set to have a lowest flow restriction.

53. The system of claim 47, wherein a ratio of a maximum internal diameter of the supply header conduit to a maximum internal diameter of each of the supply branch conduits is between about 2:1 and about 10:1.

54. The system of claim 47, wherein the liquid coolant is selected and the supply header conduit is configured so that, during operation of the system, liquid coolant flowing in the supply header conduit has a Reynolds number of between 500 and 7000.

55. The system of claim 47, wherein a pressure loss in the supply header conduit between a position of the supply branch conduit closest to an inlet side of the supply header conduit and the supply branch conduit furthest from the inlet side of the supply header conduit is between about 0.25 kPa and about 1 kPa.

56. The system of claim 47, further including a branch interconnect to selectively fluidly couple the supply branch conduit of each cooling tank to the return branch conduit of the respective tank.

57. The system of claim 47, wherein the diameter of the branch conduits is between 30% and 50% of the diameter of at least one of the inlet conduit and the outlet conduit.
